(19) United States
(12) Patent Application Publication
(10) Pub. No.: US 2025/0221198 A1
(43) Pub. Date: Jul. 3, 2025

(54) DISPLAY DEVICE

(71) Applicant: LG Display Co., Ltd., Seoul (KR)

(72) Inventors: Mihee SHIN, Paju-si (KR); JungChul KIM, Paju-si (KR)

(73) Assignee: LG Display Co., Ltd., Seoul (KR)

(21) Appl. No.: 18/819,853

(22) Filed: Aug. 29, 2024

(30) Foreign Application Priority Data
Dec. 29, 2023 (KR) 10-2023-0196884

(51) Int. Cl. H10K 59/131; H10K 59/121; H10K 59/35

(52) U.S. Cl. CPC H10K 59/131; H10K 59/1213; H10K 59/351; H10K 59/353

(57) ABSTRACT

A display device can include a substrate having a display area for displaying an image and a non-display area, a plurality of subpixels included in the display area and each including light emitting devices, and a plurality of data lines for supplying data signals to the subpixels. The display area can include a first area capable of transmitting light and a second area located outside the first area. The second area can include an upper area above the first area and a lower area under the first area. The data lines can include a first data line passing through all the upper area, the first area and the lower area, an upper data line disposed in the upper area, a lower data line disposed in the lower area, and a bypass line configured to electrically connect the upper data line and the lower data line and bypass the first area.

### CROSS-REFERENCE TO RELATED APPLICATION

This application claims priority to Korean Patent Application No. 10-2023-0196884, filed in the Republic of Korea on Dec. 29, 2023, the entire contents of which is hereby expressly incorporated by reference into the present application.

### BACKGROUND

### Field

Embodiments of the present disclosure relate to a display device.

### Discussion the Related Art

As technology advances, a display device can provide shooting functions and various sensing functions in addition to image display functions. Accordingly, a display device is needed to equip with electronic devices such as a camera and a detection sensor (which can also be referred as a light receiving device or sensor).

Since an electronic device can receive light from the front of a display device, so the electronic device is required to be installed in a location capable of receiving the light. Therefore, in general display devices, a camera (i.e., a camera lens) and a detection sensor are exposed to the front. As a result, a bezel of the display device can become larger or there can be significant limitations in the design of the display device.

### SUMMARY OF THE DISCLOSURE

Embodiments of the present disclosure can provide a display device having a light-transmitting structure which allows an electronic device to normally receive light (e.g., visible light, infrared light, or ultraviolet light) without exposing the electronic device receiving light to the front.

Embodiments of the present disclosure can provide a display device capable of improving the transmittance of an optical area (e.g., a first area) through which light can pass through.

Embodiments of the present disclosure can provide a display device having a structure to reduce the metal ratio in an optical area (e.g., a first area) through which light can be transmitted.

Embodiments of the present disclosure can provide a display device having a panel structure capable of improving a detection performance of a detection sensor using light passing through an optical area (e.g., a first area).

Embodiments of the present disclosure can provide a display device having a panel structure capable of improving a performance of a camera using light passing through an optical area (e.g., a first area).

A display device according to embodiments of the present disclosure can include a substrate including a display area capable of displaying an image and a non-display area outside the display area, a plurality of subpixels included in the display area, each of the plurality of subpixels including a plurality of light emitting devices, and a plurality of data lines for supplying data signals for image display to the plurality of subpixels.

The display area can include a first area capable of transmitting light and a second area located outside the first area. The second area can include an upper area above the first area and a lower area under the first area.

The plurality of data lines can include an upper data line disposed in the upper area, a lower data line disposed in the lower area, and a bypass line configured to electrically connect the upper data line and the lower data line and bypass the first area.

The bypass line can include a first bypass line connected to the upper data line, a second bypass line connected to the lower data line, and a third bypass line for connecting the first bypass line and the second bypass line.

The bypass line can include a horizontal bypass line extending horizontally, and a vertical bypass line extending vertically, and wherein the first bypass line and the second bypass line are horizontal bypass lines, and the third bypass line is a vertical bypass line.

The horizontal bypass line can be disposed in a first metal layer, and the vertical bypass line can be disposed in a second metal layer different from the first metal layer. Each of the plurality of light emitting devices can include a plurality of pixel electrodes.

The plurality of pixel electrodes can include a first pixel electrode disposed in the upper area and included in a first subpixel, a second pixel electrode disposed in the upper area and included in a second subpixel, a third pixel electrode disposed in the first area and included in a third subpixel, a fourth pixel electrode disposed in the first area and included in a fourth subpixel, a fifth pixel electrode disposed in the lower area and included in a fifth subpixel, and a sixth pixel electrode disposed in the lower area and included in the sixth subpixel.

The first data line can be connected to the first subpixel, the third subpixel, and the fifth subpixel. The upper data line can be connected to the second subpixel. The lower data line can be connected to the sixth subpixel.

In a display device according to embodiments of the present disclosure, the third pixel electrode and the fourth pixel electrode can be electrically connected to each other.

An emission color of each of the first subpixel, the second subpixel, the third subpixel, the fourth subpixel, the fifth subpixel, and the sixth subpixel can be the same.

Each of the first subpixel, the second subpixel, the third subpixel, the fifth subpixel, and the sixth subpixel can include a light emitting device and a subpixel circuit for driving the light emitting device. The subpixel circuit can include two or more transistors.

The fourth subpixel can include a light emitting device, but may not include a subpixel circuit. In this case, the light emitting device of the fourth subpixel can be driven by a subpixel circuit of the third subpixel.

A driving current output from the subpixel circuit of the third subpixel can be supplied to the third pixel electrode and the fourth pixel electrode.

The display device according to embodiments of the present disclosure can further include a connection line which is disposed in the first area and electrically connects the third pixel electrode and the fourth pixel electrode.

The third pixel electrode, the connection line and the fourth pixel electrode can be integrated.

The plurality of pixel electrodes can include a seventh pixel electrode disposed in the upper area and included in a seventh subpixel, an eighth pixel electrode disposed in the second area and included in an eighth subpixel, and a ninth pixel electrode disposed in the lower area and included in the ninth subpixel.

The plurality of data lines can include a second data line connected to the seventh subpixel, the eighth subpixel and the ninth subpixel.

An emission color of each of the seventh subpixel, the eighth subpixel and the ninth subpixel can be different from an emission color of each of the first subpixel, the second subpixel, the third subpixel, the fourth subpixel, the fifth subpixel and the sixth subpixel.

The second data line can intersect and overlap a portion (e.g., the connection line) in which the third pixel electrode and the fourth pixel electrode are connected.

For example, in the first area and the second area, the first data line and the second data line can be disposed in the same metal layer and spaced apart from each other on the same plane.

As another example, the first data line and the second data line can be disposed in the same metal layer in the second area. The first data line and the second data line can be disposed on different metal layers in at least a partial area of the first area.

As an example, in the second area, the first data line and the second data line can be disposed in the same metal layer and spaced apart from each other on the same plane. The first area can include a transmission area and a non-transmission area. The first data line and the second data line can be disposed in different metal layers and can overlap in a vertical direction in the transmission area. The first data line and the second data line can be disposed in the same metal layer and spaced apart from each other on the same plane in the non-transmission area.

The display device according to embodiments of the present disclosure can further include an electronic device which is located below the substrate, overlaps with the first area, and perform a predetermined operation using light passing through the first area.

Embodiments of the present disclosure can provide a display device including a substrate including a display area capable of displaying an image and a non-display area outside the display area, a plurality of subpixels included in the display area, each of the plurality of subpixels including a plurality of pixel electrodes, and a plurality of data lines for supplying data signals for image display to the plurality of subpixels.

The display area can include a first area capable of transmitting light and a second area located outside the first area. The second area can include an upper area above the first area and a lower area under the first area.

The plurality of pixel electrodes can include a first pixel electrode disposed in the upper area and included in a first subpixel, a second pixel electrode disposed in the upper area and included in a second subpixel, a third pixel electrode disposed in the first area and included in a third subpixel, a fourth pixel electrode disposed in the first area and included in a fourth subpixel, a fifth pixel electrode disposed in the lower area and included in a fifth subpixel, and a sixth pixel electrode disposed in the lower area and included in the sixth subpixel.

The plurality of data lines can include a first data line extending from the upper area, passing through the first area to the lower area, and connected to the first subpixel, the third subpixel, and the fifth subpixel, an upper data line disposed in the upper area and connected to the second subpixel, and a lower data line disposed in the lower area and connected to the sixth subpixel.

The third pixel electrode and the fourth pixel electrode can be electrically connected to each other.

The display device according to embodiments of the present disclosure can further include a connection line which is disposed in the first area and electrically connects the third pixel electrode and the fourth pixel electrode.

According to the embodiments of the present disclosure, there can provide a display device having a light-transmitting structure which allows an electronic device to normally receive light (e.g., visible light, infrared light, or ultraviolet light) without exposing the electronic device receiving light to the front.

According to the embodiments of the present disclosure, there can provide a display device capable of improving the transmittance of an optical area (i.e, a first area) through which light can pass through.

According to the embodiments of the present disclosure, there can provide a display device having a structure to reduce the metal ratio in an optical area (e.g., a first area) through which light can be transmitted.

According to the embodiments of the present disclosure, there can provide a display device having a panel structure capable of improving a detection performance of a detection sensor using light passing through an optical area (e.g., a first area).

According to the embodiments of the present disclosure, there can provide a display device having a panel structure capable of improving a performance of a camera using light passing through an optical area (e.g., a first area).

The effects of the present disclosure are not limited to the effects described above, and other effects not described will be clearly understood by those skilled in the art from the description below.

### BRIEF DESCRIPTION OF THE DRAWINGS

FIGS. 1A, 1B and 1C illustrate display devices according to embodiments of the present disclosure.

FIG. 2 illustrates a system configuration diagram of a display device according to embodiments of the present disclosure.

FIG. 3 illustrates a display panel according to embodiments of the present disclosure.

FIG. 4 illustrates a general area, a first optical area, and a second optical area in a display panel according to embodiments of the present disclosure.

FIG. 5 illustrates signal lines arranged on a display panel according to embodiments of the present disclosure.

FIGS. 6 and 7 are plan views of an optical area of the display panel according to embodiments of the present disclosure.

FIGS. 8 and 9 are cross-sectional views of a partial area within the optical area of the display panel according to embodiments of the present disclosure.

FIG. 10 illustrates an example of signal strength when receiving and processing light passing through an optical area of a display panel according to embodiments of the present disclosure.

FIG. 11 is a plan view of a display panel according to embodiments of the present disclosure.

FIGS. 12 and 13 are plan views of a partial area within an optical area of a display panel according to embodiments of the present disclosure.

FIGS. 14 to 18 are cross-sectional views of partial areas of FIGS. 12 and 13.

FIG. 19 is a cross-sectional view of a connection area between a vertical bypass line and a horizontal bypass line in a display panel according to embodiments of the present disclosure.

### DETAILED DESCRIPTION OF THE EMBODIMENTS

Hereinafter, embodiments of the disclosure are described in detail with reference to the accompanying drawings. In assigning reference numerals to components of each drawing, the same components can be assigned the same numerals even when they are shown on different drawings. When determined to make the subject matter of the disclosure unclear, the detailed of the known art or functions can be skipped. As used herein, when a component “includes,” “has,” or “is composed of” another component, the component can add other components unless the component “only” includes, has, or is composed of” the other component. As used herein, the singular forms “a”, “an” and “the” are intended to include the plural forms as well, unless the context clearly indicates otherwise.

Such denotations as “first,” “second,” “A,” “B,” “(a),” and “(b),” can be used in describing the components of the disclosure. These denotations are provided merely to distinguish a component from another, and the essence, order, or number of the components are not limited by the denotations.

In describing the positional relationship between components, when two or more components are described as “connected”, “coupled” or “linked”, the two or more components can be directly “connected”, “coupled” or “linked””, or another component can intervene. Here, the other component can be included in one or more of the two or more components that are “connected”, “coupled” or “linked” to each other.

When such terms as, e.g., “after”, “next to”, “after”, and “before”, are used to describe the temporal flow relationship related to components, operation methods, and fabricating methods, it can include a non-continuous relationship unless the term “immediately” or “directly” is used.

When a component is designated with a value or its corresponding information (e.g., level), the value or the corresponding information can be interpreted as including a tolerance that can arise due to various factors (e.g., process factors, internal or external impacts, or noise). Further, the term “can” fully encompasses all the meanings and coverages of the term “may.”

Hereinafter, various embodiments of the disclosure are described in detail with reference to the accompanying drawings. All the components of each display device according to all embodiments of the present disclosure are operatively coupled and configured.

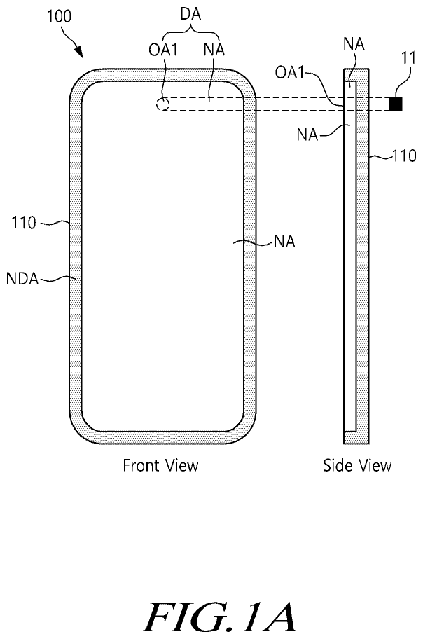

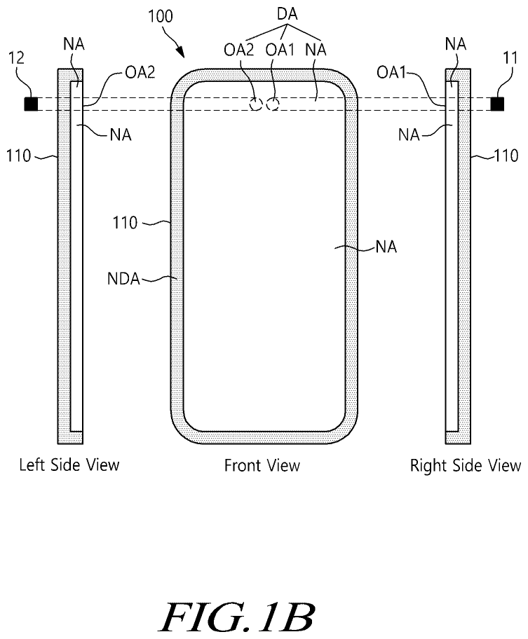

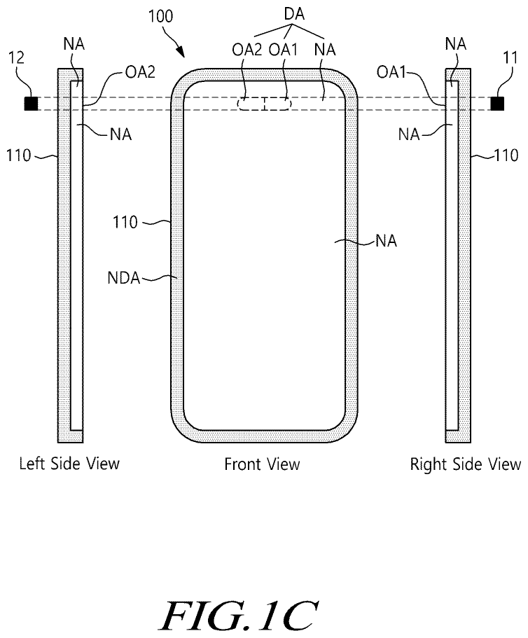

FIGS. 1A, 1B and IC illustrate a display device 100 according to embodiments of the present disclosure.

Referring to FIGS. 1A, 1B and 1C, the display device 100 according to embodiments of the present disclosure can include a display panel 110 which displays an image and one or more electronic devices 11 and 12.

The display panel 110 can include a display area DA where an image is displayed and a non-display area NDA where an image is not displayed. A plurality of subpixels and a plurality of signal lines for driving the plurality of subpixels can be disposed in the display area DA. The non-display area NDA can be an area outside the display area DA, and can surround the display area DA entirely or only in part(s). Various signal lines can be disposed in the non-display area NDA, and various driving circuits can be connected to the non-display area NDA. The non-display area NDA can be bent so that it is not visible from the front or can be obscured by a case. The non-display area NDA can be also referred as a bezel or a bezel area.

The display device 100 according to embodiments of the present disclosure can include one or more electronic devices 11 and 12 located below the display panel 110 (e.g., opposite the viewing surface). Here, one or more electronic devices 11 and 12 can be provided separately from the display panel 110.

One or more electronic devices 11 and 12 can be devices which receive light passing through the display panel 110 and perform a predetermined operation using the received light.

For example, the one or more electronic devices 11 and 12 can include one or more of a photographing device such as a camera (e.g., image sensor), a detection sensor such as a proximity sensor, and an illuminance sensor. Here, for example, the detection sensor can be an infrared sensor.

Light required for the operation of one or more electronic devices 11 and 12 can enter the front side (e.g., viewing side) of the display panel 110, pass through the display panel 110, and can be transmitted to one or more electronic devices 11 and 12 located below the display panel 110 (e.g., opposite the viewing surface). For example, light required for the operation of one or more electronic devices 11 and 12 and passing through the display panel 110 can include one or more of visible light, infrared light, and ultraviolet light.

In the display panel 110 according to embodiments of the present disclosure, the display area DA can include a general area NA and one or more optical areas OA1 and OA2. One or more optical areas OA1 and OA2 can be areas which overlap with one or more electronic devices 11 and 12.

According to the example of FIG. 1A, the display area DA can include a general area NA and a first optical area OA1. Here, at least a portion of the first optical area OA1 can overlap with the first electronic device 11.

According to the example of FIG. 1B, the display area DA can include a general area NA, a first optical area OA1, and a second optical area OA2. In the example of FIG. 1B, the general area NA can exist between the first optical area OA1 and the second optical area OA2. Here, at least a portion of the first optical area OA1 can overlap with the first electronic device 11, and at least a portion of the second optical area OA2 can overlap with the second electronic device 12.

According to the example of FIG. 1C, the display area DA can include a general area NA, a first optical area OA1, and a second optical area OA2. In the example of FIG. 1C, the general area NA may not exist between the first optical area OA1 and the second optical area OA2. For example, the first optical area OA1 and the second optical area OA2 can be in contact with each other. Here, at least a portion of the first optical area OA1 can overlap with the first electronic device 11, and at least a portion of the second optical area OA2 can overlap with the second electronic device 12.

One or more optical areas OA1 and OA2 are required to include both an image display structure and a light transmission structure. For example, since one or more optical areas OA1 and OA2 are part of the display area DA, light emitting areas of subpixels for image display are required to be disposed in the one or more optical areas OA1 and OA2. Additionally, a light transmission structure is required to be formed in one or more optical areas OA1 and OA2 to transmit light to one or more electronic devices 11 and 12.

One or more electronic devices 11 and 12 can be located behind (e.g., below or opposite to the viewing surface) the display panel 110 and receive light passing through the display panel 110.

One or more electronic devices 11 and 12 can be not exposed to the front (e.g., viewing side) of the display panel 110. Accordingly, when the user looks at the front of the display device 110, the electronic devices 11 and 12 can be not visible to the user.

For example, a first electronic device 11 can be a camera which receives light (e.g., visible light) in the visible light wavelength band, and a second electronic device 12 can be a detection sensor such as a proximity sensor or illuminance sensor. For example, the detection sensor can be an infrared sensor for detecting light (e.g., infrared rays) in the infrared wavelength band. Alternatively, the first electronic device 11 can be a detection sensor, and the second electronic device 12 can be a camera.

Hereinafter, for convenience of explanation, there is exemplified a case in which the first electronic device 11 is a camera and the second electronic device 12 is an infrared-based detection sensor. Here, the camera can be a camera lens or an image sensor.

In the case that the first electronic device 11 is a camera, the camera can be located behind (e.g., below) the display panel 110, but can be a front camera for photographing the front direction of the display panel 110. Accordingly, the user can view a viewing surface of the display panel 110 and take pictures (self-photographs) using a camera which is not visible to the viewing surface.

The general area NA and one or more optical areas OA1 and OA2 included in the display area DA can be areas where an image can be displayed. However, the general area NA can be an area in which a light transmission structure does not need to be formed, and one or more optical areas OA1 and OA2 can be areas in which a light transmission structure is required to be formed.

Therefore, one or more optical areas OA1 and OA2 are required to have transmittance above a specific level, and the general area NA may not have light transmittance or can have low transmittance below a specific level.

For example, one or more optical areas OA1 and OA2 and the general area NA can have different resolutions, subpixel arrangement structures, number of subpixels per unit area, electrode structures, line structures, electrode arrangement structures, or line arrangement structures etc.

For example, the number of subpixels per unit area in one or more optical areas OA1 and OA2 can be smaller than the number of subpixels per unit area in the general area NA. For example, the resolution of one or more optical areas OA1 and OA2 can be lower than the resolution of the general area NA. Here, the number of subpixels per unit area can mean the same as resolution, pixel density, or pixel integration. For example, a unit of the number of subpixels per unit area can be PPI (Pixels Per Inch), which means the number of pixels in 1 inch.

For example, the number of subpixels per unit area in the first optical area OA1 can be less than the number of subpixels per unit area in the general area NA. The number of subpixels per unit area in the second optical area OA2 can be greater than or equal to the number of subpixels per unit area in the first optical area OA1, and can be less than the number of subpixels per unit area in the general area NA.

Meanwhile, as a method to increase the transmittance of at least one of the first optical area OA1 and the second optical area OA2, there can be applied a differential pixel density design method, as described above. According to the differential pixel density design method, the display panel 110 can be designed so as for the number of subpixels per unit area of at least one of the first optical area OA1 and the second optical area OA2 to be less than the number of subpixels per unit area of the general area NA.

However, in some cases, a differential pixel size design method can be applied as another method to increase the transmittance of at least one of the first optical area OA1 and the second optical area OA2. According to the differential pixel size design method, the display panel 110 can be designed so as for the number of subpixels per unit area of at least one of the first optical area OA1 and the second optical area OA2 to be the same as or similar to the number of subpixels per unit area of the general area NA, but for a size of each subpixel SP (e.g., the size of the light emitting area) disposed in at least one of the first optical area OA1 and the second optical area OA2 to be smaller than the size of each subpixel SP (e.g., the size of the light emitting area) placed in the general area NA.

Hereinafter, for convenience of explanation, it will be described by assuming that the differential pixel density design method is applied among two methods (differential pixel density design method, differential pixel size design method) for increasing the transmittance of at least one of the first optical area OA1 and the second optical area OA2. Accordingly, hereinafter, a small number of subpixels per unit area can be an expression corresponding to a small subpixel size, and a large number of subpixels per unit area can be an expression corresponding to a large subpixel size.

The first optical area OA1 can have various shapes such as circular, oval, square, hexagon, or octagon. The second optical area OA2 can have various shapes, such as circular, oval, square, hexagon, or octagon. The first optical area OA1 and the second optical area OA2 can have the same shape or different shapes.

Referring to FIG. 1C, in the case that the first optical area OA1 and the second optical area OA2 are in contact, the entire optical area including the first optical area OA1 and the second optical area OA2 can also have various shapes, such as circular, oval, square, hexagon, or octagon. Hereinafter, for convenience of explanation, it will be exemplified a case in which each of the first optical area OA1 and the second optical area OA2 has a circular shape.

In the display device 100 according to the embodiments of the present disclosure, if the first electronic device 11, which is not exposed to the outside and is hidden at the bottom of the display panel 100, is a camera, a display device 100 according to embodiments of the present disclosure can be referred as a display device to which UDC (Under Display Camera) technology is applied.

Accordingly, in the display device 100 according to embodiments of the present disclosure, there may not be required to be formed a notch or camera hole for camera exposure in the display panel 110, so that there is no reduction in area of the display area DA. Accordingly, since a notch or camera hole for camera exposure does not need to be formed in the display panel 110, the size of the bezel area can be reduced, design restrictions can be eliminated, and the degree of freedom in design can be increased.

In the display device 100 according to embodiments of the present disclosure, although the one or more electronic devices 11 and 12 are hidden behind the display panel 110, the one or more electronic devices 11 and 12 are required to be able to receive light normally and normally perform a designated function thereof.

In addition, in the display device 100 according to embodiments of the present disclosure, although the one or more electronic devices 11 and 12 are hidden behind the display panel 110 and are located overlapping with the display area DA, there is required that the normal image display function is possible in one or more optical areas OA1 and OA2 overlapping with one or more electronic devices 11 and 12 in the display area DA.

Since the above-mentioned first optical area OA1 is designed as a transmissive area, a image display characteristics in the first optical area OA1 can be different from those in the general area NA.

In addition, when designing the first optical area OA1 to improve image display characteristics, there is a possibility that the transmittance of the first optical area OA1 can decrease.

Therefore, embodiments of the present disclosure can provide a structure of the first optical area OA1 capable of improving the transmittance in the first optical area OA1 while preventing image quality deviation between the first optical area OA1 and the general area NA.

In addition, embodiments of the present disclosure can provide, for the second optical area OA2 in addition to the first optical area OA1, a structure of the second optical area OA2 capable of improving the image quality and the transmittance in the second optical area OA2.

In addition, in the display device 100 according to embodiments of the present disclosure, the first optical area OA1 and the second optical area OA2 are similar in that they are light-transmission areas, but the usage examples thereof can be different from each other.

Therefore, in the display device 100 according to embodiments of the present disclosure, the structure of the first optical area OA1 and the structure of the second optical area OA2 are basically similar or the same, but a resolution, a subpixel arrangement structure, the number of subpixels per unit area, a electrode structure, a line structure, a electrode arrangement structure or a line arrangement structure thereof can be different from each other.

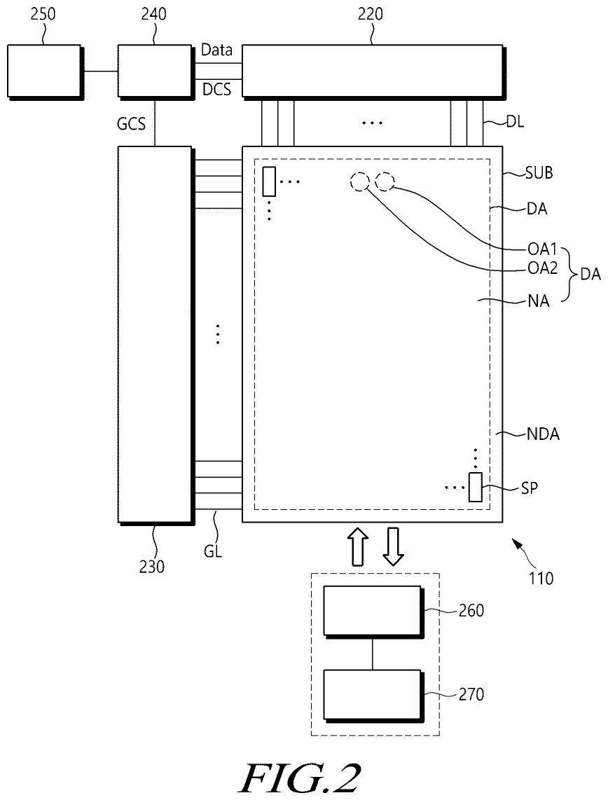

FIG. 2 illustrates a system configuration diagram of a display device 100 according to embodiments of the present disclosure.

Referring to FIG. 2, the display device 100 can include a display panel 110 and a display driving circuit as components for displaying an image. The display driving circuit can be a circuit for driving the display panel 110, and can include a data driving circuit 220, a gate driving circuit 230 and a display controller 240.

The display panel 110 can include a display area DA for displaying an image and a non-display area NDA where an image is not displayed. The non-display area NDA can be an area outside the display area DA, and can also be referred to as a bezel area. All or part of the non-display area NDA can be an area visible from the front of the display device 100, or can be an area which is bent and not visible from the front of the display device 100.

The display panel 110 can include a substrate SUB and a plurality of subpixels SP disposed on the substrate SUB. Additionally, the display panel 110 can further include various types of signal lines to drive the plurality of subpixels SP.

The display device 100 according to embodiments of the present disclosure can be a liquid crystal display device or the like, or can be a self-luminous display device in which the display panel 110 emits light on its own. When the display device 100 according to embodiments of the present disclosure is a self-luminous display device, each of the plurality of subpixels SP can include a light emitting device. For example, the display device 100 according to embodiments of the present disclosure can be an organic light emitting display device in which a light emitting device is implemented as an organic light emitting diode (OLED). For another example, the display device 100 according to embodiments of the present disclosure can be an inorganic light emitting display device in which the light emitting device is implemented as an inorganic-based light emitting diode. For another example, the display device 100 according to embodiments of the present disclosure can be a quantum dot display device in which a light emitting device is implemented with quantum dots, which are self-luminous semiconductor crystals.

The structure of each of the plurality of subpixels SP can vary depending on the type of the display device 100. For example, if the display device 100 is a self-luminous display device in which subpixels SP emit light by themselves, each subpixel SP can include a light emitting device emitting light by itself, one or more transistors, and one or more capacitors.

For example, various types of signal lines can include a plurality of data lines DL transmitting data signals (also called data voltages or image signals) and a plurality of gate lines GL transmitting gate signals (also called scan signals).

The plurality of data lines DL and the plurality of gate lines GL can cross each other. Each of the plurality of data lines DL can be arranged to extend in a first direction. Each of the plurality of gate lines GL can be arranged to extend in a second direction. Here, the first direction can be a column direction and the second direction can be a row direction. Alternatively, the first direction can be a row direction and the second direction can be a column direction. Hereinafter, for convenience of explanation, it will be exemplified a case in which each of the plurality of data lines DL is arranged in a column direction, and each of the plurality of gate lines GL is arranged in a row direction.

The data driving circuit 220 is a circuit for driving a plurality of data lines DL and connecting the plurality of data lines DL, and can output data signals to the plurality of data lines DL. The gate driving circuit 230 is a circuit for driving a plurality of gate lines GL, and can output gate signals to the plurality of gate lines GL.

The display controller 240 can be a device for controlling the data driving circuit 220 and the gate driving circuit 230, and can control the driving timing for the plurality of data lines DL and the driving timing of the plurality of gate lines GL.

The display controller 240 can supply a data driving control signal DCS to the data driving circuit 220 to control the data driving circuit 220, and can supply a gate driving control signal GCS to the gate driving circuit 230 to control the gate driving circuit 230.

The display controller 240 can receive input image data from a host system 250 and supply image data to the data driving circuit 220 based on the input image data.

The data driving circuit 220 can receive image data in digital form from the display controller 240 and convert the received image data into analog data signals to output to a plurality of data ines DL.

The gate driving circuit 230 can receive a first gate voltage corresponding to the turn-on level voltage and a second gate voltage corresponding to the turn-off level voltage along with various gate driving control signals GCS, and can generate gate signals and supply the generated gate signals to the plurality of gate lines GL.

For example, the data driving circuit 220 can be connected to the display panel 110 using a tape automated bonding (TAB) method, or can be connected to the bonding pad of the display panel 110 using a chip-on-glass (COG) or chip-on panel (COP) method, or can be implemented using a chip-on-film (COF) method and connected to the display panel 110.

The gate driving circuit 230 can be connected to the display panel 110 using a tape automated bonding (TAB) method, or can be connected to the bonding pad of the display panel 110 using a chip-on-glass (COG) or chip-on-panel (COP) method, or can be implemented using a chip-on-film (COF) method and connected to the display panel 110. Alternatively, the gate driving circuit 230 can be a gate in panel (GIP) type and can be formed in the non-display area NDA of the display panel 110. The gate driving circuit 230 can be disposed on or connected to the substrate. For example, if the gate driving circuit 230 is a GIP type, the gate driving circuit 230 can be disposed in the non-display area NDA of the substrate. The gate driving circuit 230 can be connected to the substrate if the gate driving circuit 230 is a chip-on-glass (COG) type, a chip-on-film (COF) type, etc.

Meanwhile, at least one of the data driving circuit 220 and the gate driving circuit 230 can be disposed in the display area DA of the display panel 110. For example, at least one of the data driving circuit 220 and the gate driving circuit 230 can be arranged not to overlap the subpixels SP, or can be arranged to partially or entirely overlap with the subpixels SP.

The data driving circuit 220 can be connected to one side (e.g., the upper or lower side) of the display panel 110. Depending on the driving method, panel design method, etc., the data driving circuit 220 can be connected to both sides (e.g., upper and lower sides) of the display panel 110, or can be connected to two or more of the four sides of the display panel 110.

The gate driving circuit 230 can be connected to one side (e.g., left or right side) of the display panel 110. Depending on the driving method, panel design method, etc., the gate driving circuit 230 can be connected to both sides (e.g., left and right side) of the display panel 110, or can be connected to two or more of the four sides of the display panel 110.

The display controller 240 can be implemented as a separate component from the data driving circuit 220, or can be integrated with the data driving circuit 220 and implemented as an integrated circuit.

The display controller 240 can be a timing controller used in typical display technology, or can be a control device capable of further performing other control functions including a timing controller, or can be a control device different from the timing controller, or can be a control device other than a timing controller, or can be a circuit within the control device. The display controller 240 can be implemented with various circuits or electronic components, such as an integrated circuit (IC), a field programmable gate array (FPGA), an application specific integrated circuit (ASIC), or Processor.

The display controller 240 can be mounted on a printed circuit board, a flexible printed circuit, etc., and can be electrically connected to the data driving circuit 220 and the gate driving circuit 230 through a printed circuit board, a flexible printed circuit.

The display controller 240 can transmit and receive signals with the data driving circuit 220 according to one or more predetermined interfaces. For example, the interface can include a low voltage differential signaling (LVDS) interface, an embedded clock point-point interface (EPI), or a serial peripheral interface (SPI).

In order to provide not only an image display function but also a touch sensing function, the display device 100 according to embodiments of the present disclosure can include a touch sensor and a touch sensing circuit for detecting an occurrence of a touch by a touch object such as a finger or pen or detection a touch position by sensing the touch sensor.

The touch sensing circuit can include a touch driving circuit 260 for driving and sensing a touch sensor to generate and output touch sensing data, and a touch controller 270 for detecting the occurrence of a touch or detecting the touch position using touch sensing data.

The touch sensor can include a plurality of touch electrodes. The touch sensor can further include a plurality of touch lines to electrically connect a plurality of touch electrodes and the touch driving circuit 260.

The touch sensor can exist outside the display panel 110 in the form of a touch panel or can exist inside the display panel 110. If the touch sensor exists outside the display panel 110 in the form of a touch panel, the touch sensor can be referred to as an external type. If the touch sensor is an external type, the touch panel and the display panel 110 can be manufactured separately and combined during the assembly process. The external touch panel can include a touch panel substrate and a plurality of touch electrodes on the touch panel substrate.

If the touch sensor exists inside the display panel 110, the touch sensor can be formed on the substrate SUB along with signal lines and electrodes related to display driving during the manufacturing process of the display panel 110.

The touch driving circuit 260 can supply a touch driving signal to at least one of the plurality of touch electrodes and generate touch sensing data by sensing at least one of the plurality of touch electrodes.

The touch sensing circuit can perform touch sensing using a self-capacitance sensing method or a mutual-capacitance sensing method.

If the touch sensing circuit performs touch sensing using a self-capacitance sensing method, the touch sensing circuit can perform touch sensing based on the capacitance between each touch electrode and a touch object (e.g., finger, pen, etc.). According to the self-capacitance sensing method, each of the plurality of touch electrodes can serve as a driving touch electrode and a sensing touch electrode. The touch driving circuit 260 can drive all or part of the plurality of touch electrodes and sense all or part of the plurality of touch electrodes.

If the touch sensing circuit performs touch sensing using the mutual-capacitance sensing method, the touch sensing circuit can perform touch sensing based on the capacitance between touch electrodes. According to the mutual-capacitance sensing method, the plurality of touch electrodes can be divided into driving touch electrodes and sensing touch electrodes. The touch driving circuit 260 can drive driving touch electrodes and sense sensing touch electrodes.

The touch driving circuit 260 and the touch controller 270 included in the touch sensing circuit can be implemented as separate devices or as one device. Additionally, the touch driving circuit 260 and the data driving circuit 220 can be implemented as separate devices or as one device.

The display device 100 can further include a power supply circuit which supplies various types of power to the display driving circuit and/or the touch sensing circuit.

The display device 100 according to embodiments of the present disclosure can be a mobile terminal such as a smart phone or tablet, or a monitor or television of various sizes, but is not limited thereto, and can be a display of various types and sizes capable of displaying information or images.

As described above, in the display panel 110, the display area DA can include a general area NA and one or more optical areas OA1 and OA2. The general area NA and one or more optical areas OA1 and OA2 can be areas in which images can be displayed. However, the general area NA can be an area in which a light transmission structure does not need to be formed, and the one or more optical areas OA1 and OA2 can be areas in which a light transmission structure needs to be formed.

As described above, the display area DA in the display panel 110 can include one or more optical areas OA1 and OA2 along with the general area NA. However, for convenience of explanation, it is assumed that the display area DA includes both the first optical area OA1 and the second optical area OA2 (FIGS. 1B and 1C).

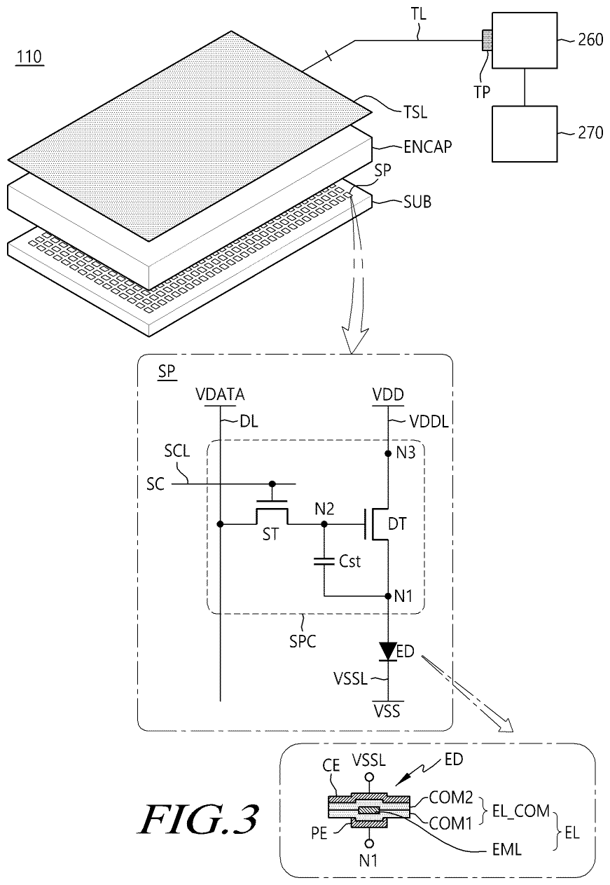

FIG. 3 illustrates a display panel 110 according to embodiments of the present disclosure.

Referring to FIG. 3, a plurality of subpixels SP can be disposed in the display area DA of the display panel 110. A plurality of subpixels SP can be disposed in the general area NA, the first optical area OA1, and the second optical area OA2 included in the display area DA.

Each of the plurality of subpixels SP can include a light emitting device ED and a subpixel circuit SPC configured to drive the light emitting device ED.

The subpixel circuit SPC can include a driving transistor DT for driving the light emitting device ED, a scan transistor ST for transferring the data voltage VDATA to the driving transistor DT, and a storage capacitor Cst for maintaining a constant voltage during one frame.

The driving transistor DT can include a first node N1, a second node N2, and a third node N3.

The first node N1 can be electrically connected to the light emitting device ED. The second node N2 can be connected to the scan transistor ST. The third node N3 can be connected to a driving voltage line VDDL.

The first node N1 can be electrically connected to the pixel electrode PE of the light emitting device ED. The data voltage VDATA can be applied to the second node N2. A driving voltage VDD can be applied to the third node N3.

The first node N1 can be a source node or a drain node, the second node N2 can be a gate node, and the third node N3 can be a drain node or a source node. Hereinafter, for convenience of explanation, in the driving transistor DT, it will be exemplified a case in which the first node N1 is a source node, the second node N2 is a gate node, and the third node N3 is a drain node.

The light emitting device ED can include a pixel electrode PE, an intermediate layer EL, and a common electrode CE.

The pixel electrode PE can be an electrode disposed in each subpixel SP. For example, the pixel electrode PE can be electrically connected directly or indirectly (via another transistor) to the first node N1 of the driving transistor DT of each subpixel SP.

The common electrode CE can be an electrode commonly disposed in the plurality of subpixels SP. For example, the common electrode CE can be electrically connected to a base voltage line VSSL. A base voltage VSS, which is a type of common driving voltage, can be applied to the common electrode CE through the base voltage line VSSL.

For example, the pixel electrode PE can be an anode electrode, and the common electrode CE can be a cathode electrode. Alternatively, the pixel electrode PE can be a cathode electrode, and the common electrode CE can be an anode electrode. Hereinafter, for convenience of explanation, it is assumed that the pixel electrode PE is an anode electrode and the common electrode CE is a cathode electrode.

The intermediate layer EL can include an emission layer EML and a common intermediate layer EL_COM.

For example, the emission layer EML can be disposed in each of the plurality of subpixels SP, or in another example, can be commonly disposed in the plurality of subpixels SP. The common intermediate layer EL_COM can be commonly disposed across the plurality of subpixels SP.

The emission layer EML can be disposed in each emission area EA, and the common intermediate layer EL_COM can be commonly disposed across the plurality of emission areas EA and the non-emission area.

The common intermediate layer EL_COM can include a first common intermediate layer COM1 and a second common intermediate layer COM2. The first common intermediate layer COM1 can be disposed between the pixel electrode PE and the emission layer EML, and can include at least one layer (e.g., an organic layer). The second common intermediate layer COM2 can be disposed between the emission layer EML and the common electrode CE, and can include at least one layer (e.g., an organic layer).

For example, the first common intermediate layer COM1 can include a hole injection layer HIL and a hole transfer layer HTL. The second common intermediate layer COM2 can include an electron transport layer ETL, an electron injection layer EIL, and the like.

The hole injection layer can inject holes from the pixel electrode PE to the hole transport layer, the hole transport layer can transport holes to the emission layer EML, and the electron injection layer can inject electrons from the common electrode CE to the electron transport layer, and the electron transport layer can transport electrons to the emission layer EML.

Each light emitting device ED can include an overlapping portion of a pixel electrode PE, an emission layer EML in the intermediate layer EL, and a common electrode CE. A predetermined emission area EA can be formed by each light emitting device ED. For example, the emission area EA can be defined as an area where the pixel electrode PE, the emission layer EML in the intermediate layer EL, and the common electrode CE overlap.

For example, the light emitting device ED can be an organic light emitting diode (OLED) based on organic materials, an inorganic light emitting diode based on inorganic materials, or a quantum dot light emitting device. in the case that the light emitting device ED is an organic light emitting diode, the intermediate layer EL in the light emitting device ED can include an organic layer containing an organic material.

The scan transistor ST can be controlled on-off by a scan signal SC as a type of gate signal applied through the scan signal line SCL as a type of gate line GL, and can be electrically connected between the second node N2 of the driving transistor DT and the data line DL.

The storage capacitor Cst can be electrically connected between the first node N1 and the second node N2 of the driving transistor DT.

The subpixel circuit SPC can have a 2T (Transistor)-1C (Capacitor) structure including two transistors DT and ST and one capacitor Cst, as shown in FIG. 3, and can further include one or more transistors or one or more capacitors in some case.

The storage capacitor Cst can be an external capacitor intentionally designed outside the driving transistor DT rather than a parasitic capacitor (e.g., Cgs, Cgd) as an internal capacitor which can exist between the first node N1 and the second node N2 of the driving transistor DT. Each of the driving transistor DT and scan transistor ST can be an n-type transistor or a p-type transistor.

The circuit elements within each subpixel SP (in particular, light emitting devices EDs implemented with organic light emitting diodes (OLEDs) containing organic materials) can be vulnerable to external moisture or oxygen. Therefore, there can be disposed an encapsulation layer ENCAP on the display panel 110 to prevent oxygen from penetrating into the circuit elements (particularly, the light emitting device ED). The encapsulation layer ENCAP can be disposed to cover the light emitting devices ED.

The display device 100 according to embodiments of the present disclosure can include, in order to sense the user's touch, a touch sensor layer TSL including a plurality of sensor electrodes, a touch driving circuit 260 configured to sense a plurality of sensor electrodes, and a touch controller 270 configured to determine the presence or absence of a touch or touch coordinates using the sensing result (e.g., touch sensing data) of the touch driving circuit 260.

The touch sensor layer TSL can be embedded into the display panel 110. For example, the touch sensor layer TSL can be disposed on the encapsulation layer ENCAP within the display panel 110.

The display panel 110 can further include a plurality of touch pads TP electrically connected to the touch driving circuit 260, and a plurality of touch routing lines TL for electrically connecting a plurality of sensor electrodes included in the touch sensor layer TSL to a plurality of touch pads TP connected to the touch driving circuit 260.

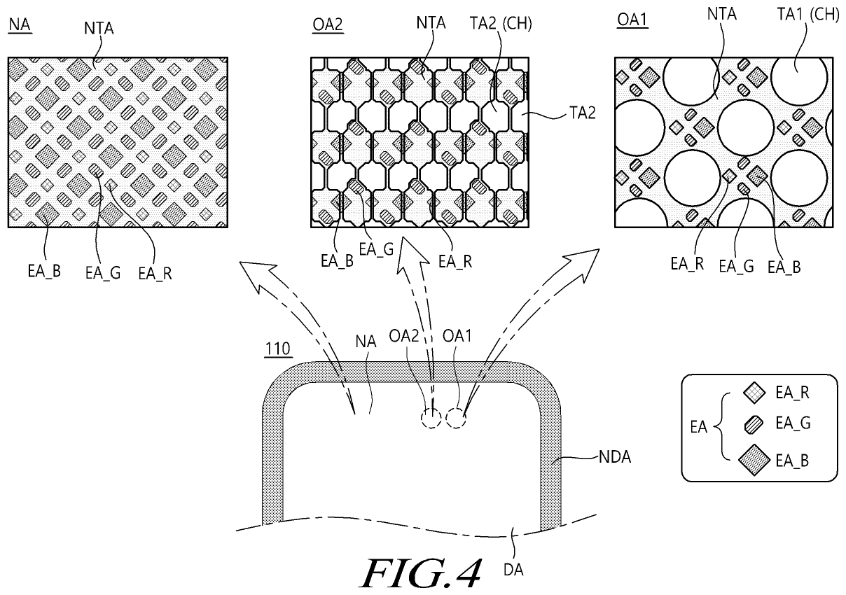

FIG. 4 illustrates a general area NA, a first optical area OA1, and a second optical area OA2 in a display panel 110 according to embodiments of the present disclosure.

Referring to FIG. 4, the display panel 110 according to embodiments of the present disclosure can include a display area DA where an image is displayed and a non-display area NDA where an image is not displayed. The display area DA can include a first optical area OA1, a second optical area OA2, and a general area NA.

Since the first optical area OA1, the second optical area OA2, and the general area NA are included in the display area DA, they can have a display structure. For example, each of the first optical area OA1, the second optical area OA2 and the general area NA can include a plurality of emission areas EA.

In addition, the first optical area OA1 and the second optical area OA2 can be areas through which light can be transmitted, and the general area NA can be an area through which light cannot be transmitted or where light transmission is minimal. The general area NA can refer to an area through which light cannot be transmitted, excluding the first optical area OA1 and the second optical area OA2. Here, the light transmission can mean that light passes between the front and back surfaces of the display panel 110.

The first optical area OA1 can be an area which overlaps with the first electronic device 11. The second optical area OA2 can be an area which overlaps the second electronic device 12.

Each of the first optical area OA1 and the second optical area OA2 can have a light transmission structure. However, the first optical area OA1 and the second optical area OA2 can have different structural characteristics. For example, the transmittance of the first optical area OA1 can be higher than the transmittance of the second optical area OA2. The resolution or the number of subpixels per unit area of the first optical area OA1 can be lower or smaller than the resolution or the number of subpixels per unit area of the second optical area OA2.

The first electronic device 11 can perform a predetermined operation using light in a first wavelength band among the light passing through the first optical area OA1. The second electronic device 12 can perform a predetermined operation using light in a second wavelength band different from the first wavelength band among the light transmitting through the second optical area OA2.

The first wavelength band can include one or more of a visible light wavelength band, an infrared wavelength band, and an ultraviolet wavelength band. The second wavelength band includes one or more of a visible light wavelength band, an infrared wavelength band, and an ultraviolet wavelength band, but can be different from the first wavelength band.

For example, the first electronic device 11 can be a camera and the second electronic device 12 can be a detection sensor. The first electronic device 11 can perform a camera operation using light in the visible light wavelength band corresponding to the first wavelength band among the light passing through the first optical area OA1. The second electronic device 12 can perform a sensing operation using light in an infrared wavelength band corresponding to the second wavelength band among the light transmitting through the second optical area OA2.

Each of the first optical area OA1 and the second optical area OA2 can be circular or octagonal. However, the present disclosure is not limited thereto, each of the first optical area OA1 and the second optical area OA2 can have various shapes, such as an elliptical or oval shape, a polygonal shape, or an irregular shape.

The first optical area OA1 and the second optical area OA2 can have the same shape. Alternatively, the first optical area OA1 and the second optical area OA2 can have different shapes.

The display area DA can include a plurality of emission areas EA. Since the general area NA, the first optical area OA1 and the second optical area OA2 are areas included in the display area DA, each of the general area NA, first optical area OA1 and second optical area OA2 can include a plurality of emission areas EA.

The plurality of emission areas EA can include emission areas emitting light of three or more colors. For example, the plurality of emission areas EA can include a first color emission area emitting first color light, a second color emission area that emitting second color light, and a third color emission area emitting third color light.

For example, if the first color light is red light, the second color light is green light, and the third color light is blue light, the first color emission area can be referred to as a red emission area EA_R, the second color emission area can be referred to as a green emission area EA_G, and the third color emission area can be referred to as a blue emission area EA_B.

The red emission area EA_R, green emission area EA_G and blue emission area EA_B can have the same size (e.g., emission area size). Alternatively, at least one of the red emission area EA_R, green emission area EA_G and blue emission area EA_B can have a size (e.g., emission area size) different from the others.

As described above, the first color, second color, and third color can be different colors, and can be various colors. For example, the first color, second color and third color can be red, green and blue, respectively. Hereinafter, for convenience of explanation, it will be exemplified a case in which the first color is red, the second color is green, and the third color is blue, However, is not limited thereto.

In the case that the first color is red, the second color is green, and the third color is blue, the size of the blue emission area EA_B (e.g., emission area size) can be the largest among the size of the red emission area EA_R (e.g., emission area size), the size of the green emission area EA_G (e.g., emission area size), and the size of the blue emission area EA_B (e.g., emission area size).

The light emitting device ED disposed in the red emission area EA_R can include an emission layer EML emitting red light. The light emitting device ED disposed in the green emission area EA_G can include an emission layer EML emitting green light. The light emitting device ED disposed in the blue emission area EA_B can include an emission layer EML emitting blue light.

Among the emission layer EML emitting red light, the emission layer EML emitting green light, and the emission layer EML emitting blue light, the organic material contained in the emission layer EML emitting blue light can be the most susceptible to material deterioration. Accordingly, by designing the size of the blue emission area EA_B to be the largest, the current density supplied to the light emitting device ED disposed in the blue emission area EA_B can be minimal. Therefore, the degree of deterioration of the light emitting device ED disposed in the blue emission area EA_B can become similar to the degree of deterioration of the light emitting device ED disposed in the red emission area EA_R and the light emitting device ED disposed in the green emission area EA_G.

Therefore, there can be eliminated or reduced a deterioration variation between the light emitting device ED disposed in the red emission area EA_R, the light emitting device ED disposed in the green emission area EA_G, and the light emitting device ED disposed in the blue emission area EA_B, thereby improving image quality.

Each of the plurality of first transmission areas TA1 included in the first optical area OA1 can have various shapes such as circular, oval, polygonal, or irregular shapes. Each of the plurality of second transmission areas TA2 included in the second optical area OA2 can have various shapes, such as circular, oval, polygonal, or irregular shapes.

The plurality of first transmission areas TA1 can have the same shape. Alternatively, some of the plurality of first transmission areas TA1 can have a shape different from the others. The plurality of second transmission areas TA2 can have the same shape. Alternatively, some of the plurality of second transmission areas TA2 can have a different shape from the others.

The first transmission area TA1 and the second transmission area TA2 can have the same shape. Alternatively, the first transmission area TA1 and the second transmission area TA2 can have different shapes.

The general area NA can all correspond to a non-transmission area. For example, the general area NA can include a non-transmission area NTA including a plurality of emission areas EA. For example, the entire general area NA can be a non-transmission area NTA, and the general area NA may not include the transmission area TA.

The first optical area OA1 can further include a non-transmission area NTA including a plurality of emission areas EA and a plurality of first transmission areas TA1. The non-transmission area NTA included in the first optical area OA1 can be an area through which no light is transmitted, or can be an area where light is transmitted with a lower transmittance than the first transmission area TA1.

The second optical area OA2 can further include a non-transmission area NTA including a plurality of emission areas EA, and a plurality of second transmission areas TA2. The non-transmission area NTA included in the second optical area OA2 can be an area through which no light is transmitted, or can be an area through which light is transmitted with a lower transmittance than the second transmission area TA2.

Meanwhile, the common electrode CE can include a plurality of common electrode holes CH corresponding to a plurality of openings. A plurality of common electrode holes CH can be formed in the first optical area OA1 and the second optical area OA2. For example, positions where the plurality of common electrode holes CH are formed can be the first optical area OA1 and the second optical area OA2.

The positions where the plurality of common electrode holes CH are formed in the common electrode CE can correspond to the plurality of first transmission areas TA1 included in the first optical area OA1, respectively. In addition, positions where the plurality of common electrode holes CH are formed in the common electrode CE can respectively correspond to the plurality of second transmission areas TA2 included in the second optical area OA2. Accordingly, the transmittance of each of the first optical area OA1 and the second optical area OA2 can be improved.

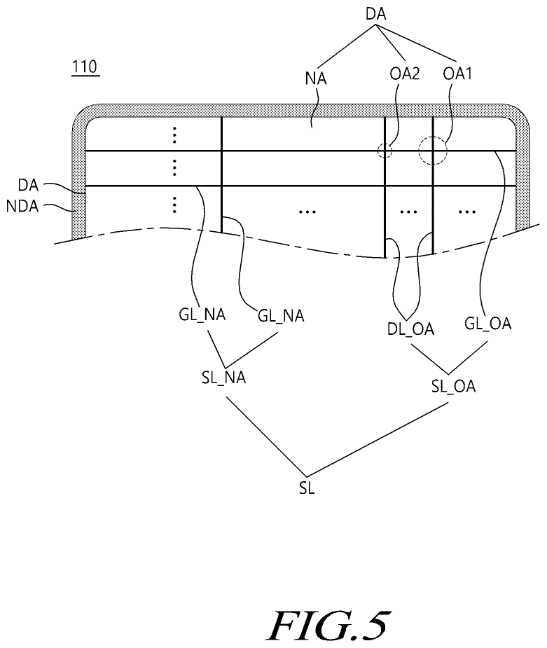

FIG. 5 illustrates signal lines SL arranged on a display panel 110 according to embodiments of the present disclosure.

Referring to FIG. 5, the display panel 110 according to embodiments of the present disclosure can include a plurality of subpixels SP and a plurality of signal lines SL for driving the plurality of subpixels SP).

Each of the plurality of subpixels SP can include a light emitting device ED and a subpixel circuit SPC for driving the light emitting device ED. The emission area EA can be formed by the light emitting device ED.

The plurality of signal lines SL can supply various driving signals necessary for driving the plurality of subpixels SP to the plurality of subpixels SP.

For example, various driving signals can include a data signal VDATA for driving the data line DL and a scan signal SC for driving the gate line GL. The various driving signals can further include a driving voltage VDD for driving the driving voltage line VDDL and a base voltage VSS for driving the base voltage line VSSL connected to the common electrode CE.

Accordingly, the plurality of signal lines can include a plurality of data lines DL for supplying data signals VDATA and a plurality of gate lines GL for supplying gate signals such as scan signals SC. The plurality of signal lines can further include a driving voltage line VDDL for supplying the driving voltage VDD and a base voltage line VSSL for supplying the base voltage VSS.

The display area DA can include a general area NA, a first optical area OA1, and a second optical area OA2.

Each of the general area NA, the first optical area OA1 and the second optical area OA2 can include a plurality of emission areas EA. A plurality of light emitting devices ED and a plurality of subpixel circuits SPC can be disposed in each of the general area NA, the first optical area OA1 and the second optical area OA2.

The plurality of signal lines SL can include a plurality of general signal lines SL_NA and a plurality of specific signal lines SL_OA.

The plurality of general signal lines SL_NA can be signal lines disposed only in the general area NA without passing through the first optical area OA1 and the second optical area OA2.

The plurality of specific signal lines SL_OA can be signal lines passing through at least one of the first optical area OA1 and the second optical area OA2.

For example, a plurality of general signal lines SL_NA can include a plurality of data lines DL_NA and a plurality of gate lines GL_NA which do not pass through the first optical area OA1 and the second optical area OA2.

For example, a plurality of specific signal lines SL_OA can include a plurality of data lines DL_OA and a plurality of gate lines DL_OA passing through at least one of the first optical area OA1 and the second optical area OA2.

As described above, since the plurality of specific signal lines SL_OA pass through at least one of the first optical area OA1 and the second optical area OA2, the transmission characteristics of the first optical area OA1 and the second optical area OA2 can be influenced by a plurality of specific signal lines SL_OA.

Meanwhile, positions where the plurality of common electrode holes CH are formed in the common electrode CE can respectively correspond to the plurality of first transmission areas TA1 included in the first optical area OA1. In addition, positions where the plurality of common electrode holes CH are formed in the common electrode CE can respectively correspond to the plurality of second transmission areas TA2 included in the second optical area OA2. Accordingly, the transmittance of each of the first optical area OA1 and the second optical area OA2 can be improved.

In order to further increase the transmittance of the first optical area OA1, when the plurality of specific signal lines SL_OA pass through the first optical area OA1, the plurality of specific signal lines SL_OA can be arranged to bypass the plurality of common electrode holes CH corresponding to the plurality of first transmission areas TA1. Similarly, in order to further increase the transmittance of the second optical area OA2, when the plurality of specific signal lines SL_OA pass through the second optical area OA2, the plurality of specific signal lines SL_OA can be arranged to bypass the plurality of common electrode holes CH corresponding to the plurality of second transmission areas TA2.

In this case, a plurality of specific signal lines SL_OA passing through at least one of the first optical area OA1 and the second optical area OA2 can have a line length greater than the plurality of general signal lines SL_NA which do not pass through the first optical area OA1 and the second optical area OA2.

Accordingly, the plurality of specific signal lines SL_OA and the plurality of general signal lines SL_NA can have different electrical characteristics (e.g., different line resistance, different signal transmission delays, etc.). As a result, the driving characteristics between the subpixels SP connected to the plurality of specific signal lines SL_OA and the subpixels SP connected to the plurality of general signal lines SL_NA can become different, which can cause deterioration in image quality.

Meanwhile, when manufacturing the display panel 110, there can be performed a process for patterning the common electrode CE having a plurality of common electrode holes CH. In this case, if a change in the patterning process of the common electrode CE occurs, the transmittance of the plurality of common electrode holes CH of the common electrode CE can change, and there can occur the transmittance difference between the plurality of common electrode holes CH.

Accordingly, the display panel 110 according to embodiments of the present disclosure can have a line characteristic deviation reduction structure.

According to the line characteristic deviation reduction structure according to embodiments of the present disclosure, there can be reduced a deviation in electrical characteristics (e.g., deviation in line resistance, deviation in signal transmission delay, etc.) between the plurality of specific signal lines SL_OA passing through at least one of the first optical area OA1 and the second optical area OA2 and the plurality of general signal lines SL_NA which do not pass through the first optical area OA1 and the second optical area OA2.

In addition, the display panel 110 according to embodiments of the present disclosure can have a structure to reduce the range of transmittance variation.

According to the structure for reducing the transmittance variation range according to the embodiments of the present disclosure, the transmittance variation range between the plurality of common electrode holes CH can be reduced even if process change occurs. Here, the plurality of common electrode holes CH can correspond to a plurality of first transmission areas TA1 in the first optical area OA1 or a plurality of second transmission areas TA2 in the second optical area OA2, respectively.

Hereinafter, for convenience of explanation, the first optical area OA1 and the second optical area OA2 are referred to as an optical area OA, and the first transmission area TA1 in the first optical area OA1 and the second transmission area TA2 in the second optical area OA2 are referred to as a transmission area TA.

Hereinafter, it will be described a structure for improving the transmission characteristics of the optical area OA of the display panel 110 according to embodiments of the present disclosure with reference to a plurality of exemplary drawings.

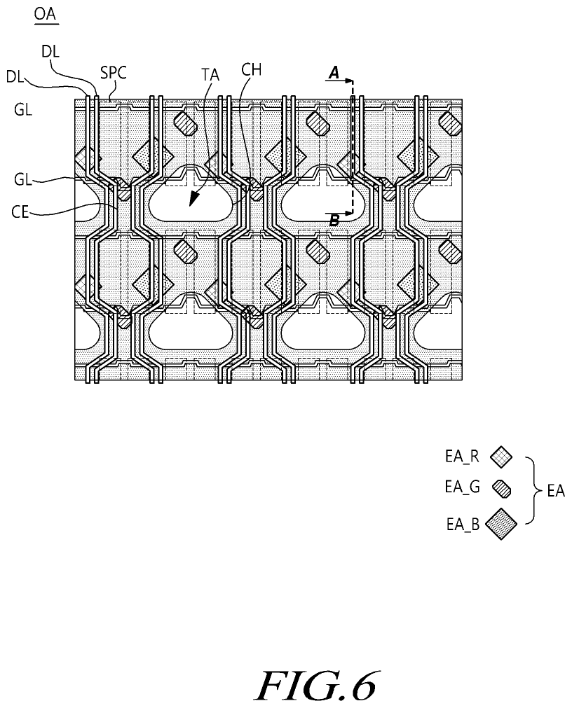

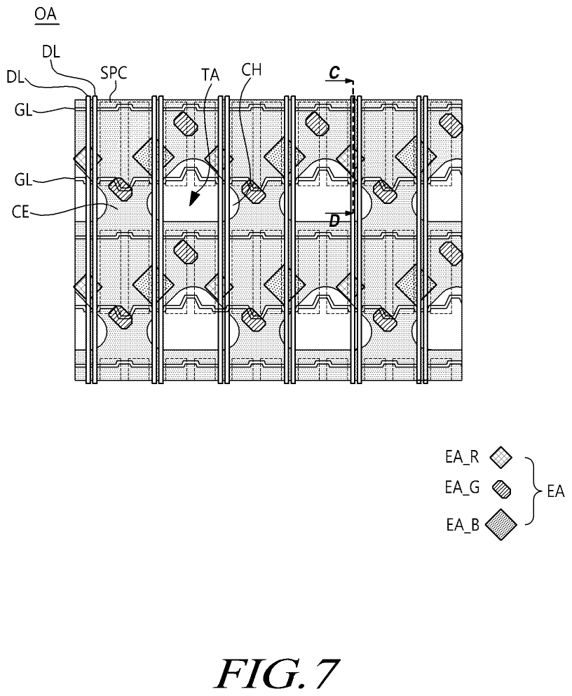

FIGS. 6 and 7 are plan views of an optical area OA of the display panel 110 according to embodiments of the present disclosure.

Referring to FIGS. 6 and 7, the display panel 110 according to embodiments of the present disclosure can include a substrate SUB including a display area DA on which an image is displayed, a plurality of signal lines SL disposed on the substrate SUB, and a common electrode CE disposed on the substrate SUB.

The display area DA can include an optical area OA through which light is transmitted and a general area NA located outside the optical area OA. The general area NA can include a plurality of emission areas EA.

The optical area OA can include a plurality of transmission areas TA and a non-transmission area NTA excluding the plurality of transmission areas TA.

The non-transmission area NTA included in the optical area OA can include a plurality of emission areas EA formed by a plurality of light emitting device ED. Additionally, a plurality of subpixel circuits SPC can be disposed in the non-transmission area NTA included in the optical area OA.

The common electrode CE can include a plurality of common electrode holes CH. The location where the plurality of common electrode holes CH are formed can be the optical area OA. For example, a plurality of common electrode holes CH can exist in the optical area OA.

The plurality of common electrode holes CH can be positioned to respectively correspond to the plurality of transmission areas TA.

As described above, the plurality of signal lines SL can include a plurality of general signal lines SL which do not pass through the optical area OA, and a plurality of specific signal lines SL_OA which pass through the optical area OA.

For example, a plurality of specific signal lines SL_OA passing through the optical area OA can include a plurality of data lines DL. The plurality of specific signal lines SL_OA passing through the optical area OA can include a plurality of gate lines GL.

Referring to FIG. 6, a plurality of data lines DL passing through the optical area OA can be arranged while bypassing a plurality of transmission areas TA.

Accordingly, the transmittance of the optical area OA can be improved.

Referring to FIG. 7, the plurality of data lines DL passing through the optical area OA can be disposed across at least one of the plurality of transmission areas TA without bypassing the plurality of transmission areas TA.

Accordingly, the length deviation between the plurality of data lines DL passing through the optical area OA and the plurality of data lines DL not passing through the optical area OA can be reduced, so that the signal transmission characteristic deviation (e.g., line characteristic deviation) can be reduced.

Each of the plurality of common electrode holes CH can overlap with the plurality of data lines DL passing through the optical area OA.

Each of the plurality of common electrode holes CH illustrated in FIGS. 6 and 7 can be triangular. However, this only an example, and the common electrode hole CH can have various shapes.

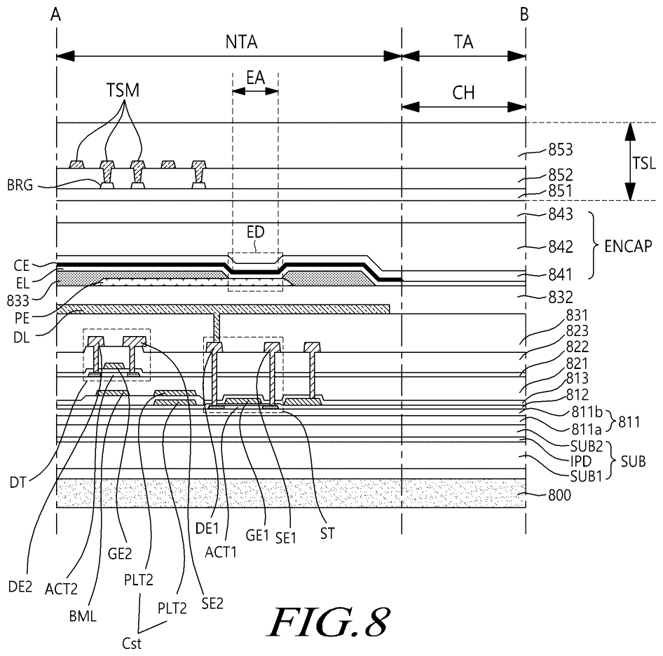

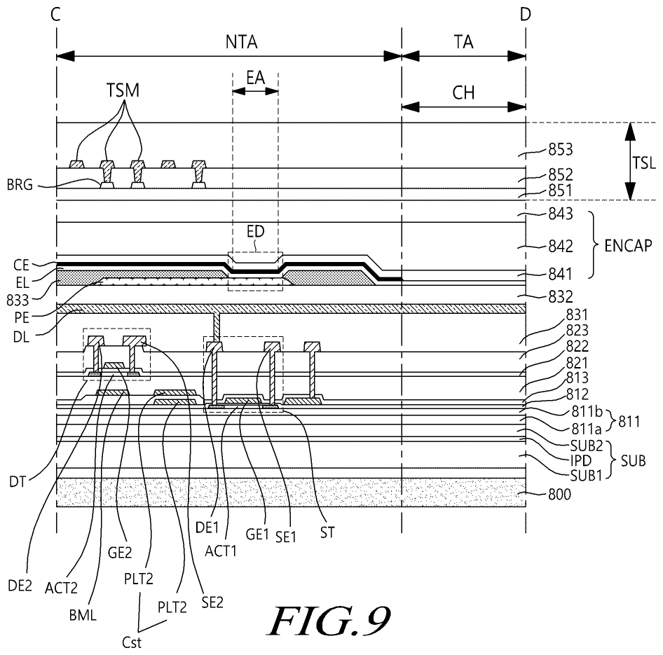

FIGS. 8 and 9 are cross-sectional views of a partial area within the optical area of the display panel according to embodiments of the present disclosure. Particularly, FIG. 8 is a cross-sectional view taken along line A-B of FIG. 6, and FIG. 9 is a cross-sectional view taken along line C-D of FIG. 7.

Referring to FIGS. 8 and 9, the display panel 110 according to embodiments of the present disclosure can include a substrate SUB including a display area DA on which an image is displayed, a plurality of signal lines SL disposed on the substrate SUB, and a common electrode CE disposed on the substrate SUB.

An optical area OA can include a plurality of emission areas EA and a plurality of transmission areas TA.

The common electrode CE can include a plurality of common electrode holes CH. The plurality of common electrode holes CH can be positioned to respectively correspond to the plurality of transmission areas TA.

The display panel 110 according to embodiments of the present disclosure can include a pixel electrode PE disposed in one emission area EA among the plurality of emission areas EA included in the optical area OA, a driving transistor DT disposed in the optical area OA for supplying driving current to the pixel electrode PE, a capacitor Cst disposed in the optical area OA, a bank 833 disposed on the pixel electrode PE and having an opening, and an intermediate layer EL disposed between the bank 833 and the common electrode CE and located on a portion of the pixel electrode PE through the opening of the bank 833.

An area where the pixel electrode PE, the intermediate layer EL and the common electrode CE overlap can constitute one light emitting device ED, and can correspond to one emission area EA.

The driving transistor DT and the capacitor Cst can be disposed in a non-transmission area NTA other than the plurality of transmission areas TA within the optical area OA.

The display panel 110 according to embodiments of the present disclosure can further include a scan transistor ST disposed in an area other than the plurality of transmission areas TA within the optical area OA.

The scan transistor ST can be connected to a data line DL, which is one of the plurality of specific signal lines SL_OA.

The data line DL, which is a specific signal line SL_OA connected to the scan transistor ST among the plurality of specific signal lines SL_OA, can be disposed within a metal layer located between the source and drain electrodes of the driving transistor DT and the pixel electrode PE.

The display panel 110 according to embodiments of the present disclosure can further include an encapsulation layer ENCAP disposed on the common electrode CE, and a touch sensor metals TSM disposed on the encapsulation layer ENCAP and located in the general area NA and the optical area OA.

The touch sensor metals TSM can overlap with the bank 833. Among the touch sensor metals TSM, the touch sensor metals TSM disposed in the optical area OA can be located in a non-transmission area NTA excluding the plurality of emission areas EA and the plurality of transmission areas TA within the optical area OA.

Hereinafter, it will be described a vertical structure of the display panel 110 in more detail with reference to FIGS. 8 and 9.

Referring to FIGS. 8 and 9, the display panel 110 according to embodiments of the present disclosure can include a transistor forming portion, a light emitting device forming portion, and an encapsulation portion when viewed from a vertical structure, and can further include a touch sensor portion.

The display panel 110 according to embodiments of the present disclosure can include a substrate SUB, a first buffer layer 811 on the substrate SUB, a first gate insulating layer 812 on the first buffer layer 811, a first interlayer insulating layer 813 on the first gate insulating layer 812, a second buffer layer 821 on the first interlayer insulating layer 813, a second gate insulating layer 822 on the second buffer layer 821, a second interlayer insulating layer 823 on the second gate insulating layer 822, a first planarization layer 831 on the second interlayer insulating layer 823, and a second planarization layer 832 on the first planarization layer 831.

The display panel 110 according to embodiments of the present disclosure can further include a first gate metal layer located between the first gate insulating layer 812 and the first interlayer insulating layer 813, a first source-drain metal layer located between the second interlayer insulating layer 823 and the first planarization layer 831, and a second source-drain metal layer located between the first planarization layer 831 and the second planarization layer 832.

The display panel 110 according to embodiments of the present disclosure can further include a second gate metal layer between the first interlayer insulating layer 813 and the second buffer layer 821, and a third gate metal layer between the second gate insulating layer 822 and the second interlayer insulating layer 823.

The display panel 110 according to embodiments of the present disclosure can further includes a first active layer ACT1 between the first buffer layer 811 and the first gate insulating layer 812, and a second active layer ACT2 between the second buffer layer 821 and the second gate insulating layer 822.

The transistor forming portion can include a substrate SUB, a first buffer layer 811 on the substrate SUB, and various transistors DT and ST, a storage capacitor Cst, and various electrodes or signal lines.

The substrate SUB can include a first substrate SUB1 and a second substrate SUB2, and can include an intermediate substrate layer IPD between the first substrate SUB1 and the second substrate SUB2. For example, each of the first substrate SUB1 and the second substrate SUB2 can include polyimide PI. For example, the intermediate substrate layer IPD can be an inorganic layer and can block moisture penetration.

The first buffer layer 811 can be a single layer or a multi-layer. If the first buffer layer 811 is a multi-layer, the first buffer layer 811 can include a multi-buffer layer 811a and an active buffer layer 811b.

The transistors DT and ST, the storage capacitors Cst, and various electrodes or signal lines can be formed on the first buffer layer 811.

For example, the transistors DT and ST formed on the first buffer layer 811 can be made of the same material and can be located in the same layers. Alternatively, as shown in FIGS. 8 and 9, the driving transistor DT and the scan transistor ST can be made of different materials and located in different layers.

The driving transistor DT, scan transistor ST, and storage capacitor Cst can be included in subpixel circuit SPC for driving the light emitting device ED included in the optical area OA.

The scan transistor ST can include an active layer ACT1, a gate electrode GE1, a source electrode SE1, and a drain electrode DE1.

The driving transistor DT can include an active layer ACT2, a gate electrode GE2, a source electrode SE2, and a second drain electrode DE2.

The active layer ACT2 of the driving transistor DT can be located higher than the active layer ACT1 of the scan transistor ST. Depending on the height of the active layer, there can be distinguished an upper transistor and a lower transistor. The driving transistor DT can also be referred to as an upper transistor, and the scan transistor ST can also be referred to as a lower transistor.

The source electrode SE1 and drain electrode DE1 of the scan transistor ST, which is the lower transistor, can be located in “a first source-drain metal layer.” The gate electrode GE1 of the scan transistor ST, which is the lower transistor, can be located in “a first gate metal layer”.

The source electrode SE2 and drain electrode DE2 of the driving transistor DT, which is the upper transistor, can be located in “a first source-drain metal layer.” The gate electrode GE2 of the driving transistor DT, which is the upper transistor, can be located in another “a third gate metal layer” higher than the first gate metal layer and the second gate metal layer.

The first buffer layer 811 can be disposed under the active layer ACT1 of the scan transistor ST, and a second buffer layer 821 can be disposed under the active layer ACT2 of the driving transistor DT. For example, the active layer ACT1 of the scan transistor ST can be located on the first buffer layer 811, and the active layer ACT2 of the driving transistor DT can be located on the second buffer layer 821. Here, the second buffer layer 821 can be located higher than the first buffer layer 811.

The active layer ACT1 of the scan transistor ST can be disposed on the first buffer layer 811, and the first gate insulating layer 812 can be disposed on the active layer ACT1 of the scan transistor ST. The gate electrode GE of the scan transistor ST can be disposed on the first gate insulating layer 812, and the first interlayer insulating layer 813 can be disposed on the gate electrode GE1 of the scan transistor ST.

Here, the active layer ACT1 of the scan transistor ST can include a channel region overlapping with the gate electrode GE1, a source connection region located on one side of the channel region, and a drain connection region located on the other side of the channel region.

The second buffer layer 821 can be disposed on the first interlayer insulating layer 813.

The active layer ACT2 of the driving transistor DT can be disposed on the second buffer layer 821, and the second gate insulating layer 822 can be disposed on the active layer ACT2 of the driving transistor DT. The gate electrode GE2 of the driving transistor DT can be disposed on the second gate insulating layer 822, and the second interlayer insulating layer 823 can be disposed on the gate electrode GE2 of the driving transistor DT.

Here, the active layer ACT2 of the driving transistor DT can include a channel region overlapping with the gate electrode GE2, a source connection region located on one side of the channel region, and a drain connection region located on the other side of the channel region.

The source electrode SE2 and the drain electrode DE2 of the driving transistor DT can be disposed on the second interlayer insulating layer 823. Additionally, the source electrode SE1 and the drain electrode DE1 of the scan transistor ST can be disposed on the second interlayer insulating layer 823.

The source electrode SE1 and drain electrode DE1 of the scan transistor ST can be connected to the source connection region and the drain connection region of the active layer ACT1 of the scan transistor ST, respectively, through the through holes of the second interlayer insulating layer 823, the second gate insulating layer 822, the second buffer layer 821, the first interlayer insulating layer 813, and the first gate insulating layer 812.

The source electrode SE2 and drain electrode DE2 of the driving transistor DT can be connected to the source connection region and the drain connection region of the active layer ACT2 of the driving transistor DT, respectively, through the through holes of the second interlayer insulating layer 823 and the second gate insulating layer 822.

The storage capacitor Cst can include a first capacitor electrode PLT1 and a second capacitor electrode PLT2.

The first capacitor electrode PLT1 of the storage capacitor Cst can be electrically connected directly or indirectly to the gate electrode GE2 of the driving transistor DT, and the second capacitor electrode PLT2 of the storage capacitor Cst can be electrically connected directly or indirectly to the source electrode SE2 of the driving transistor DT.

The first capacitor electrode PLT1 of the storage capacitor Cst can be located within the first gate metal layer made of the first gate metal. The second capacitor electrode PLT2 of the storage capacitor Cst can be located in a second gate metal layer made of a second gate metal.

Meanwhile, a lower metal BML can be disposed under the active layer ACT2 of the driving transistor DT. The lower metal BML can overlap all or part of the active layer ACT2 of the driving transistor DT. The lower metal BML can include the second gate metal of the second gate metal layer.

For example, the lower metal BML can be electrically connected to the gate electrode GE2 of the driving transistor DT. As another example, the lower metal BML can serve as a light shield which blocks light coming from the lower part. In this case, the lower metal BML can be electrically connected to the source electrode SE2 of the driving transistor DT.

Further, a first planarization layer 831 can be disposed on the driving transistor DT and the scan transistor ST. For example, the first planarization layer 831 can be disposed on the source electrode SE2 and drain electrode DE2 of the driving transistor DT and the source electrode SE1 and drain electrode DE1 of the scan transistor ST.

A second source-drain metal layer can exist between the first planarization layer 831 and the second planarization layer 832.

The source electrode SE2 of the driving transistor DT and the pixel electrode PE of the light emitting device ED can be electrically connected through a relay pattern formed in the second source-drain metal layer.

The data line DL passing through the transmission area TA can be formed within the second source-drain metal layer. For example, the data line DL passing through the transmission area TA can include a second source-drain metal.

The active layer ACT2 of the driving transistor DT as an upper transistor, and the active layer ACT1 of the scan transistor ST as a lower transistor can include different semiconductor materials.

For example, the active layer ACT2 of the driving transistor DT as the upper transistor can include an oxide semiconductor material. For example, oxide semiconductor materials can include indium gallium zinc oxide (IGZO), indium gallium zinc tin oxide (IGZTO), zinc oxide (ZnO), cadmium oxide (CdO), indium oxide (InO), zinc tin oxide (ZTO), or zinc indium tin oxide (ZITO), etc.

For instance, the active layer ACT1 of the scan transistor ST, which is the lower transistor, can include a semiconductor material different from the active layer ACT2 of the driving transistor DT as the upper transistor.

As an example, the active layer ACT1 of the scan transistor ST, which is a lower transistor, can include a silicon-based semiconductor material. For example, the silicon-based semiconductor material can include low-temperature polycrystalline silicon (LTPS).

A light emitting device forming portion can be located on the second planarization layer PNL2.

The light emitting device forming portion can include a light emitting device ED formed on the second planarization layer PNL2. The light emitting device ED can be disposed in the optical area OA.

The light emitting device ED can be formed by overlapping a pixel electrode PE, an intermediate layer EL, and a common electrode CE. For example, the light emitting device ED can be a portion in which the pixel electrode PE, the intermediate layer EL, and the common electrode CE overlap.

The pixel electrode PE can be disposed on the second planarization layer 832.

A bank 833 can be disposed on the pixel electrode PE. The bank 833 can include a plurality of bank holes, and a portion of the pixel electrode PE can be exposed through the plurality of bank holes. For example, a plurality of bank holes formed in the bank 833 can overlap with a part of the pixel electrode PE.

The intermediate layer EL can be disposed on the bank 833. The intermediate layer EL can contact a portion of the pixel electrode PE through the bank hole.

At least one spacer can exist between the intermediate layer EL and the bank 833. The spacer can include the same material as the bank 833.

A common electrode CE can be disposed on the intermediate layer EL. The common electrode CE can include a plurality of common electrode holes CH. A plurality of common electrode holes CH formed in the common electrode CE can be disposed in the optical area OA.

The common electrode hole CH can have a location corresponding to the transmission area TA.

Referring to FIG. 8, the data line DL can be located to avoid the transmission area TA. Accordingly, the data line DL does not exist in the transmission area TA.

Referring to FIG. 9, the data line DL can be disposed while passing through the transmission area TA. Accordingly, the data line DL can exist in the transmission area TA. For example, the data line DL can be a transparent line containing a transparent material.

Referring to FIGS. 8 and 9, the encapsulation portion can be located on the cathode electrode CE. The encapsulation portion can include an encapsulation layer ENCAP formed on the common electrode CE.

The encapsulation layer ENCAP can be a layer capable of preventing moisture or oxygen from penetrating into the light emitting device ED disposed below the encapsulation layer ENCAP. In particular, the encapsulation layer ENCAP can prevent moisture or oxygen from penetrating into the intermediate layer EL, which can include an organic layer. Here, the encapsulation layer ENCAP can be formed by a single layer or multiple layers.

The encapsulation layer ENCAP can include a first encapsulation layer 841, a second encapsulation layer 842, and a third encapsulation layer 843.

For example, the encapsulation layer ENCAP can include alternating inorganic and organic layers. In this case, for example, the first encapsulation layer 841 and the third encapsulation layer 843 can be inorganic layers, and the second encapsulation layer 842 can be an organic layer. In the case that the second encapsulation layer 842 is composed of an organic layer, the second encapsulation layer 842 can serve as a planarization layer.

Meanwhile, the display panel 110 according to embodiments of the present disclosure can have a built-in touch sensor or an embedded touch sensor. In this case, the display panel 110 according to embodiments of the present disclosure can include a touch sensor layer TSL on the encapsulation layer ENCAP.

The touch sensor layer TSL can include touch sensor metals TSM and bridge metals BRG, and can further include insulating layer configurations such as a sensor buffer layer 851, a sensor interlayer insulating layer 852 and a sensor protection layer 853.

The sensor buffer layer 851 can be disposed on the encapsulation layer ENCAP.

The bridge metals BRG can be disposed on the sensor buffer layer 851, and the sensor interlayer insulating layer 852 can be disposed on the bridge metals BRG.

The touch sensor metals TSM can be disposed on the sensor interlayer insulating layer 852. Some of the touch sensor metals TSM can be connected to the corresponding bridge metal BRG through holes in the sensor interlayer insulating layer 852.

The touch sensor metals TSM and bridge metals BRG can be disposed in the general area NA and in the non-transmission area NTA in the optical area OA.

In the case that the display panel 110 has a top light-emission structure, when placing the touch sensor metals TSM and bridge metals BRG in the non-transmission area NTA in the optical area OA, the touch sensor metals TSM and bridge metals BRG can be arranged so as not to overlap the emission area EA of the non-transmission area NTA.

A plurality of touch sensor metals TSM can form one touch electrode (or one touch electrode line), and can be arranged in a mesh shape and electrically connected. A portion of the touch sensor metals TSM and another portion of the touch sensor metals TSM can be electrically connected through a bridge metal BRG to form one touch electrode (or one touch electrode line).

The sensor protection layer 853 can be disposed to cover the touch sensor metals TSM and bridge metals BRG.

Meanwhile, if the display panel 110 is a type including a built-in touch sensor, at least a portion of the touch sensor metal TSM located on the encapsulation layer ENCAP in the display area DA can be extended and disposed along the outer inclined surface of the encapsulation layer ENCAP, and can be electrically connected to a pad located further outside the outer inclined surface of the encapsulation layer ENCAP. Here, the pad can be disposed in the non-display area NDA and can be a metal pattern to which the touch driving circuit 260 is electrically connected.

Referring to FIGS. 8 and 9, the display device 100 according to embodiments of the present disclosure can include an electronic device 800 located below the substrate SUB and overlapping the optical area OA. The electronic device 800 can be one of the first electronic device 11 and the second electronic device 12 (as shown in FIGS. 1A, 1B, and IC).

The electronic device 800 can perform a determined operation according to a first light in the first wavelength band among the light transmitted through the optical area OA and received. For example, the first wavelength band can correspond to a visible light wavelength band or an infrared wavelength band.

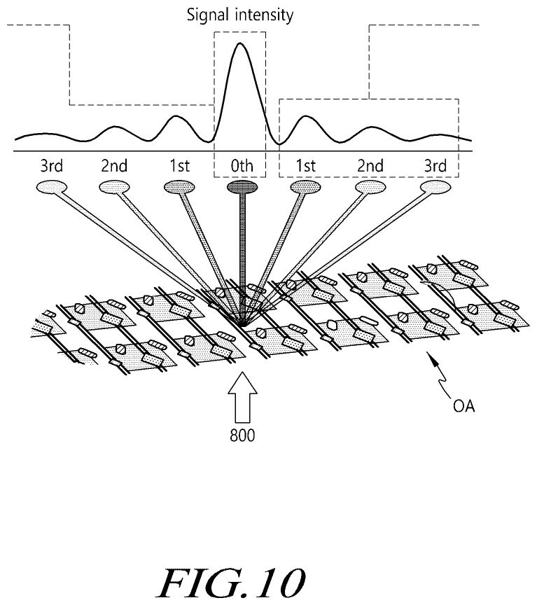

FIG. 10 illustrates an example of signal strength or signal intensity when receiving and processing light passing through an optical area OA of a display panel 110 according to embodiments of the present disclosure.

Referring to FIG. 10, light incident on the upper surface of the display panel 110 can transmits (e.g., pass through) the optical area OA of the display panel 110, and can be received by the electronic device 800 located below the display panel 110 and overlapping the optical area OA.

The electronic device 800 can perform a predetermined operation using received light.

Depending on the amount of light received by the electronic device 800, there can vary the performance and quality of operations performed by the electronic device 800.

As an example, if the electronic device 800 is an infrared sensor for detecting a nearby object, the performance and quality of a sensing operation performed using infrared rays can vary depending on the amount of infrared rays penetrating the optical area OA of the display panel 110.

The amount of infrared rays passing through the optical area OA of the display panel 110 can correspond to an intensity or a value of a point spread function (PSF). Here, the intensity of the point spread function can correspond to the signal intensity of infrared rays during reception processing by the electronic device 800. The intensity of the point spread function can be an indicator of the detection performance of the infrared sensor.

If the metal ratio in the optical area OA increases, for example, if the transmittance of the optical area OA decreases, the intensity of the point spread function, which is an indicator of the detection performance of the infrared sensor, can also decrease.

If the metal ratio in the optical area OA decreases, for example, if the transmittance of the optical area OA increases, the intensity of the point spread function, which is an indicator of the detection performance of the infrared sensor, can also increase.

As another example, in the case that the electronic device 800 is an image sensor or a camera, the performance and quality of the camera operation performed using visible light can vary depending on the amount of visible light passing through the optical area OA of the display panel 110.

The amount of visible light passing through the optical area OA of the display panel 110 can correspond to intensity or a value of a modulation transfer function (MTF). Here, the value of the modulation transfer function can correspond to the signal intensity of visible light during reception processing by the electronic device 800. Here, the value of the modulation transfer function can be an indicator of the camera performance and can indicate the level of sharpness.

If the metal ratio in the optical area OA increases, for example, if the transmittance of the optical area OA decreases, the value of the modulation transfer function, which is a performance indicator of the camera, can also decrease.

If the metal ratio in the optical area OA decreases, for example, if the transmittance of the optical area OA increases, the value of the modulation transfer function, which is a performance indicator of the camera, can increase.

Hereinafter, it will be described a transmittance improvement structure of the optical area OA of the display panel 110 according to embodiments of the present disclosure. The transmittance improvement structure of the optical area OA can include a structure capable of lowering the metal ratio in the optical area OA.

Hereinafter, for convenience of explanation, the optical area OA will be referred to as a first area OA, and the general area NA will be referred to as a second area NA.

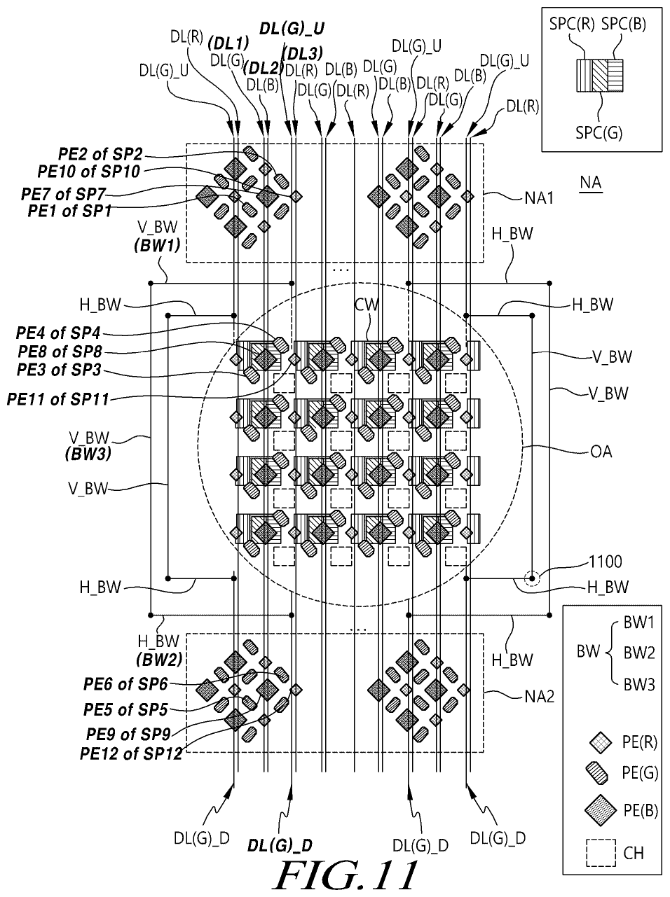

FIG. 11 is a plan view of the display panel 110 according to embodiments of the present disclosure.

Referring to FIG. 11, the display panel 110 according to embodiments of the present disclosure can include a substrate SUB including a display area DA capable of displaying an image and a non-display area NDA outside the display area DA, a plurality of subpixels SP included in the display area DA and each including a plurality of light emitting device ED, and a plurality of data lines DL for supplying data signals for image display to a plurality of subpixels SP.

The display area DA can include a first area OA capable of transmitting light and a second area NA located outside the first area OA. The second area NA can include an upper area NA1 adjacent to an upper edge of the first area OA, and a lower area NA2 adjacent to a lower edge of the first area OA.

As an example, the first area OA is indicated by a dotted circle, and an area outside the dotted circle can be the second area NA. The upper area NA1 of the second area NA can be an area located at the top of the first area OA among the outer areas of the first area OA. The lower area NA2 of the second area NA can be an area located at the bottom of the first area OA among the outer areas of the first area OA.

The plurality of subpixels SP disposed in the display area DA can include first to twelfth subpixels SP1 to SP12.

The plurality of subpixels SP disposed in the upper area NA1 of the second area NA can include the first subpixel SP1, the second subpixel SP2, and the seventh subpixel SP7, and a tenth subpixel SP10.

The plurality of subpixels SP disposed in the lower area NA2 of the second area NA can include the fifth subpixel SP5, the sixth subpixel SP6, and the ninth subpixel SP9, and a twelfth subpixel SP12.

The plurality of subpixels SP disposed in the first area OA can include a third subpixel SP3, a fourth subpixel SP4, an eighth subpixel SP8, and an eleventh subpixel SP11.

For example, the plurality of subpixels SP disposed in the display area DA can include a red subpixel which emits red light, a green subpixel which emits green light, and a blue subpixel which emits blue light.

Further, a plurality of subpixels SP disposed in the display area DA can each include a plurality of pixel electrodes PE. For example, the plurality of pixel electrodes PE can include a red pixel electrode PE(R) included in the red subpixel, a green pixel electrode PE(G) included in the green subpixel, and a blue pixel electrode PE(B) included in the blue subpixel.

The plurality of data lines DL disposed in the display area DA can include a red data line DL(R) for supplying data signals to the red subpixel, green data lines DL(G), DL(G)_U and DL(G)_D for supplying data signals to the green subpixels, and a blue data line DL(B) for supplying data signals to the blue subpixel.

A plurality of data lines DL disposed in the display area DA can be arranged in the second area NA, which is the general area NA.

Some (e.g., DL(R), DL(G), DL(B)) of the plurality of data lines DL disposed in the second area NA can pass through a first area OA, which is the optical area OA.

However, other parts (e.g., DL(G)_U and DL(G)_D) of the plurality of data lines DL disposed in the second area NA can be disposed while bypassing the first area OA, which is the optical area OA, without passing through the first area OA.

For example, an upper data line DL(G)_U can be disposed in the upper area NA1 of the second area NA, and a lower data line DL(G)_D can be disposed in the lower area NA2 of the second area NA. The upper data line DL(G)_U and the lower data line DL(G)_D can be electrically connected through a bypass line BW which bypasses the first area OA. The upper data line DL(G)_U, the lower data line DL(G)_D, and the bypass line BW can be electrically connected to correspond to a single data line, and this single data line can bypass the first area OA without passing through the first area OA.

For example, the plurality of data lines DL can include a first data line DL1 passing through all of the upper area NA1, the first area OA, and the lower area NA2.

In the example of FIG. 11, the first data line DL1 can be a green data line DL(G) for supplying a data signal to green subpixels disposed in each of the upper area NA1, the first area OA, and the lower area NA2. However, this is only an example and is not limited thereto.

The plurality of data lines DL can further include an upper data line DL(G)_U disposed in the upper area NA1 of the second area NA, a lower data line DL(G)_D disposed in the lower area NA2 of the second area NA, and a bypass line which electrically connects the upper data line DL(G)_U and lower data line DL(G)_D and bypasses the first area OA. In this case, the upper data line DL(G)_U, the lower data line DL(G)_D and bypass line BW can be electrically connected to serve as a single data line.

In the example of FIG. 11, the upper data line DL(G)_U can be a green data line DL(G)_U for supplying a data signal to the green subpixel placed in the upper area NA1. In addition, the lower data line DL(G)_D can be a green data line DL(G)_D for supplying a data signal to the green subpixel disposed in the lower area NA2. However, this is only an example and is not limited thereto.

Referring to FIG. 11, the bypass line BW can include a first bypass line BW1 connected to the upper data line DL(G)_U, a second bypass line BW2 connected to the lower data line DL(G)_D, and a third bypass line BW3 which connects the first bypass line BW1 and the second bypass line BW2.

The bypass line BW can include a horizontal bypass line H_BW extending in a horizontal direction and a vertical bypass line V_BW extending in a vertical direction, and connecting to the data driving circuit 220. Referring to FIG. 11, the horizontal bypass line H_BW and the upper data line DL(G)_U along with the lower data line DL(G)_D can form a mesh type.

Further, crossings between the bypass line BW and the upper data line DL(G)_U along with the lower data line DL(G)_D can have connecting points. For example, a first connecting point is formed at a crossing between the upper data line DL(G)_U and the first bypass line BW1 (which is a horizontal bypass line H_BW), a second connecting point is formed at a crossing between the lower data line DL(G)_D and the second bypass line BW2 (which is a horizontal bypass line H_BW), a third connecting point is formed at a crossing between the first bypass line BW1 (which is a horizontal bypass line H_BW) and the third bypass line BW3 (which is a vertical bypass line V_BW), and a fourth connecting point is formed at a crossing between the second bypass line BW2 (which is a horizontal bypass line H_BW) and the third bypass line BW3 (which is a vertical bypass line V_BW).

The horizontal bypass line H_BW can include a first bypass line BW1 and a second bypass line BW2, and the vertical bypass line V_BW can include a third bypass line BW3.

The horizontal bypass line H_BW and the vertical bypass line V_BW can intersect each other and can overlap with each other in the vertical direction.

Accordingly, the horizontal bypass line H_BW and the vertical bypass line V_BW can be disposed in different metal layers. For example, the horizontal bypass line H_BW can be disposed in a first metal layer, and the vertical bypass line V_BW can be disposed in a second metal layer different from the first metal layer. For example, the first metal layer can be a first source-drain metal layer and the second metal layer can be a second source-drain metal layer.

The plurality of pixel electrodes PE included in each of the plurality of light emitting device ED can include a first pixel electrode PE1 disposed in the upper area NA1 and included in the first subpixel SP1, a second pixel electrode PE2 disposed in the upper area NA1 and included in the second subpixel SP2, a third pixel electrode PE3 disposed in the first area OA and included in the third subpixel SP3, a fourth pixel electrode PE4 disposed in the first area OA and included in the fourth subpixel SP4, a fifth pixel electrode PE5 disposed in the lower area NA2 and included in the fifth subpixel SP5, and a sixth pixel electrode PE6 disposed in the lower area NA2 and included in the sixth subpixel SP6.

The first data line DL1 can be connected to the first subpixel SP1 in the upper area NA1, the third subpixel SP3 in the first area OA, and the fifth subpixel SP5 in the lower area NA2.

The first data line DL1 can supply data signals to the first subpixel SP1 in the upper area NA1, the third subpixel SP3 in the first area OA, and the fifth subpixel SP5 in the lower area NA2.

The upper data line DL(G)_U can be connected to the second subpixel SP2 disposed in the upper area NA1, and the lower data line DL(G)_D can be connected to the sixth subpixel SP6 disposed in the lower area NA2.

The display panel 110 according to embodiments of the present disclosure can further include a connection line CW which electrically connects the third pixel electrode PE3 and the fourth pixel electrode PE4.

The connection line CW can be disposed in the first area OA, which is the optical area OA.

The emission color of each of the first subpixel SP1, the second subpixel SP2, the third subpixel SP3, the fourth subpixel SP4, the fifth subpixel SP5, and the sixth subpixel SP6 can be the same.

In the example of FIG. 11, the emission color of each of the first subpixel SP1, the second subpixel SP2, the third subpixel SP3, the fourth subpixel SP4, the fifth subpixel SP5, and the sixth subpixel SP6 can be green, but is not limited thereto.

A part (e.g., the third subpixel SP3) of the plurality of subpixels SP3 and SP4 disposed in the first area OA can include the light emitting device ED and the subpixel circuit SPC.

The subpixel circuit SPC included in some (e.g., third subpixel (SP3)) of the plurality of subpixels SP3 and SP4 disposed in the first area OA can include a driving transistor DT, a scan transistor ST and a storage capacitor Cst, (as shown in FIG. 3).

Referring to FIG. 11, the subpixel circuit SPC included in some (e.g., third subpixel SP3) of the plurality of subpixels SP3 and SP4 disposed in the first area OA can include a red subpixel circuit SPC(R) included in the red subpixel, a green subpixel circuit SPC(G) included in the green subpixel, and a blue subpixel circuit SPC(B) included in the blue subpixel.

Another part (e.g., fourth subpixel SP4) of the plurality of subpixels SP3 and SP4 disposed in the first area OA can include a light emitting device ED, but may not include a subpixel circuit SPC.

Referring to the example of FIG. 11, each of the first subpixel SP1, the second subpixel SP2, the third subpixel SP3, the fifth subpixel SP5, and the sixth subpixel SP6 can include a light emitting device ED and a subpixel circuit PC(G) for driving the light emitting device ED. Here, the subpixel circuit SPC(G) can include two or more transistors DT and ST.

The fourth subpixel SP4 can include the light emitting device ED, but may not include the subpixel circuit SPC(G). The light emitting device ED of the fourth subpixel SP4 can be driven by the subpixel circuit SPC(G) of the third subpixel SP3.

Accordingly, the driving current output from the subpixel circuit SPC(G) of the third subpixel SP3 can be supplied to the third pixel electrode PE3, and can be also supplied to the fourth pixel electrode PE4 through the connection line CW.

A plurality of pixel electrodes PE can further include a seventh pixel electrode PE7 disposed in the upper area NA1 and included in the seventh subpixel SP7, an eighth pixel electrode PE8 disposed in the first area OA and included in the eighth subpixel SP8, and a ninth pixel electrode PE9 disposed in the lower area NA2 and included in the ninth subpixel SP9.

The plurality of data lines DL can further include a second data line DL2 connected to the seventh subpixel SP7 in the upper area NA1, the eighth subpixel SP8 in the first area OA, and the ninth subpixel SP9 in the lower area NA2.

In the example of FIG. 11, the second data line DL2 can be a blue data line DL(B) for supplying a data signal to blue subpixels disposed in each of the upper area NA1, the first area OA, and the lower area NA2, however is not limited thereto.

Emission color of each of the seventh subpixel SP7 in the upper area NA1, the eighth subpixel SP8 in the first area OA and the ninth subpixel SP9 in the lower area NA2 can be different from emission color of each of the first subpixel SP1, the second subpixel SP2, the third subpixel SP3, the fourth subpixel SP4, the fifth subpixel SP5 and the sixth subpixel SP6.

For example, the emission color of each of the first subpixel SP1, the second subpixel SP2, the third subpixel SP3, the fourth subpixel SP4, the fifth subpixel SP5 and the sixth subpixel SP6 can be green, and the emission color of the seventh subpixel SP7 in the upper area NA1, the eighth subpixel SP8 in the first area OA and the ninth subpixel SP9 in the lower area NA2 can be blue, however is not limited thereto.

Referring to FIG. 11, the second data line DL2 can intersect and overlap with the connection line CW. The first data line DL1 can also intersect and overlap with the connection line CW.

The plurality of pixel electrodes PE can further include a tenth pixel electrode PE10 disposed in the upper area NA1 and included in the tenth subpixel SP10, an eleventh pixel electrode PE11 disposed in the first area OA and included in the eleventh subpixel SP11, and a twelfth pixel electrode PE12 disposed in the lower area NA2 and included in the twelfth subpixel SP12.

The plurality of data lines DL can further include a third data line DL3 connected to the tenth subpixel SP10 of the upper area NA1, the eleventh subpixel SP11 of the first area OA, and the twelfth subpixel SP12 of the lower area NA2.

In the example of FIG. 11, the third data line DL3 can be a red data line DL(R) for supplying a data signal to the red subpixels disposed in each of the upper area NA1, the first area OA and the lower area NA2, but is not limited thereto.

Referring to FIG. 11, the emission color of each of the tenth subpixel SP10, the eleventh subpixel SP11 and the twelfth subpixel SP12 can be different from the emission color of each of the first subpixel SP1, the second subpixel SP2, the third subpixel SP3, the fourth subpixel SP4, the fifth subpixel SP5 and the sixth subpixel SP6.

For example, the emission color of each of the first subpixel SP1, the second subpixel SP2, the third subpixel SP3, the fourth subpixel SP4, the fifth subpixel SP5 and the sixth subpixel SP6 can be green, and the emission color of each of the tenth subpixel SP10, the eleventh subpixel SP11 and the twelfth subpixel SP12 can be red, however is not limited thereto.

The display panel 110 according to embodiments of the present disclosure can further include a common electrode CE disposed on the plurality of pixel electrodes PE.

Further, within the first area OA, the common electrode CE can have a plurality of common electrode holes CH. For example, within the first area OA, the common electrode CE can have a common electrode hole CH between the first data line DL1 and the third data line DL3.

The display panel 110 according to embodiments of the present disclosure can include a substrate SUB including a display area DA capable of displaying an image and a non-display area NDA outside the display area DA, a plurality of subpixels SP included in the display area DA and each including a plurality of light emitting devices ED, and a plurality of data lines DL for supplying data signals for image display to a plurality of subpixels SP.

The display area DA can include a first area OA, which is an optical area capable of transmitting light, and a second area NA, which is a general area located outside the first area OA.

The second area NA can include an upper area NA1 adjacent to an upper edge of the first area OA, and a lower area NA2 adjacent to a lower edge of the first area OA.

The plurality of light emitting devices ED can each include a plurality of pixel electrodes PE.

The plurality of pixel electrodes PE can be disposed in the first area OA, and can include two pixel electrodes PE3 and PE4 which are electrically connected to each other.

The display panel 110 according to embodiments of the present disclosure can be disposed in the first area OA, and can further include a connection line CW which electrically connects the two pixel electrodes PE3 and PE4.

The plurality of data lines DL can include a first data line DL1 connected to one of two subpixels (e.g., a subpixel including PE3) including two pixel electrodes PE3 and PE4. Among the two subpixels containing two pixel electrodes PE3 and PE4, the remaining one (e.g., the subpixel containing PE4) may not connected to the data line.

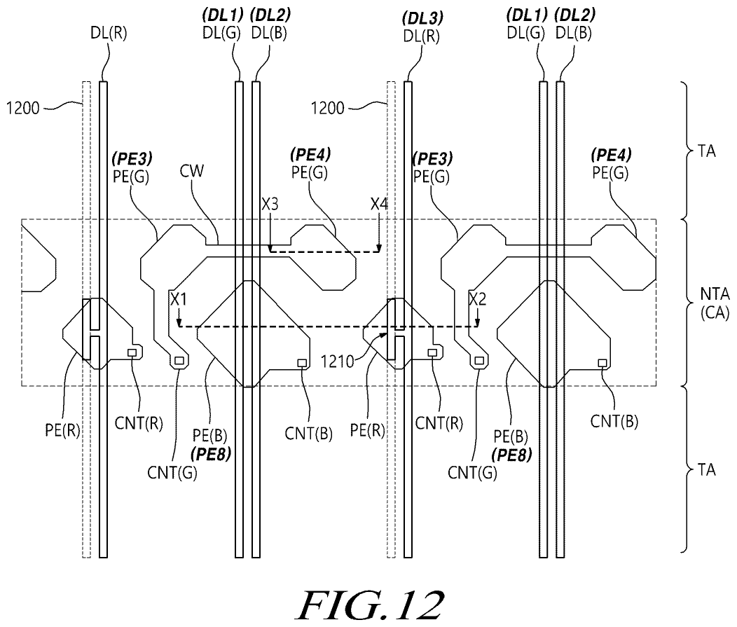

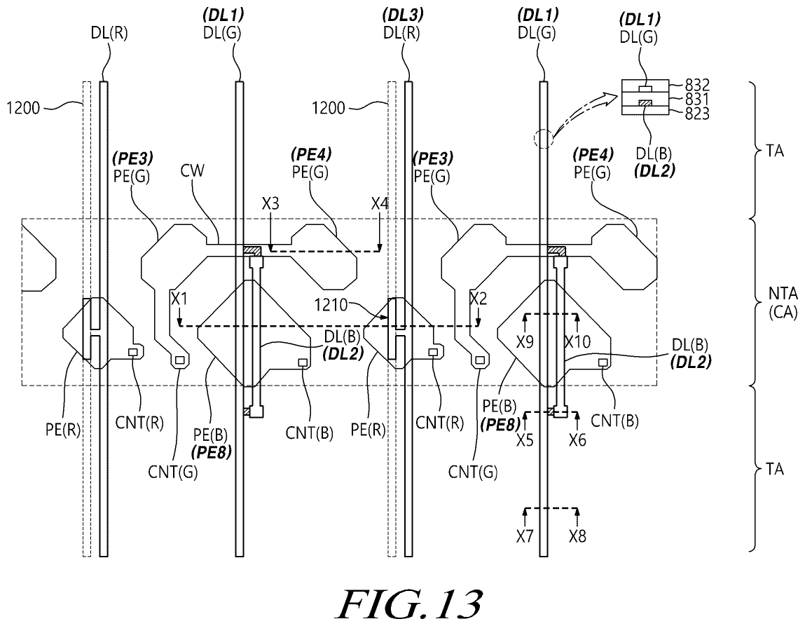

FIGS. 12 and 13 are plan views of a portion of the first area OA1, which is the optical area OA, of the display panel 110 according to embodiments of the present disclosure.

Referring to FIGS. 12 and 13, the first area OA1, which is the optical area OA of the display panel 110, can include a transmission area TA and a non-transmission area NTA.

The non-transmission area NTA can include a circuit area CA where a plurality of subpixel circuits, each included in a plurality of subpixels, are disposed. For example, the plurality of subpixel circuits can include a red subpixel circuit included in a red subpixel, a green subpixel circuit included in a green subpixel, and a blue subpixel circuit included in a blue subpixel.

The non-transmission area NTA can include a plurality of emission areas each corresponding to a plurality of subpixels. Accordingly, a plurality of pixel electrodes PE(R), PE(G) and PE(B) can be disposed in the non-transmission area NTA.

Further, a plurality of contact holes CNT(R), CNT(G) and CNT(B) can be placed in the non-transmission area NTA for connecting a plurality of pixel electrodes PE(R), PE(G) and PE(B) to a plurality of subpixel circuits, respectively.

For example, a plurality of pixel electrodes PE(R), PE(G) and PE(B) can include a red pixel electrode PE(R) included in the red subpixel, and a green pixel electrodes PE(G) included in the green subpixel, and a blue pixel electrode PE(B) included in the blue subpixel. For reference, the arrangement of the red pixel electrode PE(R), green pixel electrode PE(G) and blue pixel electrode PE(B) in FIGS. 12 and 13 is different from the arrangement of the red pixel electrode PE(R), the green pixel electrode PE(G) and blue pixel electrode PE(B) of FIG. 11.

For example, a plurality of contact holes CNT(R), CNT(G) and CNT(B) can include a contact hole CNT(R) between the red pixel electrode PE(R) and the red subpixel circuit, a contact hole CNT(G) between the green pixel electrode PE(G) and the green subpixel circuit, and a contact hole CNT(B) between the blue pixel electrode PE(B) and the blue subpixel circuit.

Further, two green pixel electrodes PE(G) can be connected by a connection line CW. The two green pixel electrodes PE(G) connected by the connection line CW can correspond to the third pixel electrode PE3 and the fourth pixel electrode PE4 of FIG. 11.

The blue pixel electrode PE(B) can correspond to the eighth pixel electrode PE8 of FIG. 11.

Referring to FIG. 11, in the second area NA which is the general area NA, four data lines (e.g., red data line, green data line, blue data line, green data line) can be arranged repeatedly.

In the upper area NA1 of the second area NA which is the general area NA, the red data line DL(R), the green data line DL(G)_U as the upper data line, and the blue data line DL(B), and the green data line DL(G) can be arranged in order.

Referring to FIG. 11, in the lower area NA2 of the second area NA which is the general area NA, a red data line DL(R), a green data line DL(G)_D as the lower data line, a blue data line DL(B), and a green data line DL(G) can be arranged in order.

Referring to FIGS. 12 and 13, in the first area OA which is the optical area OA, three data lines (e.g., red data line DL(R), blue data line DL(B), green data line DL(G)) can be arranged repeatedly.

In the first area OA, there is omitted a green data line in an area 1200 between the red data line DL(R) and the blue data line DL(B). Accordingly, metal can be reduced within the first area OA which is the optical area OA. As a result, the metal ratio in the first area OA as the optical area OA can be lowered and the transmittance can be increased.

The green data line DL(G) can correspond to the first data line DL1 in FIG. 11, and the blue data line DL(B) can correspond to the second data line DL2 in FIG. 11, and the red data line DL(R) can correspond to the third data line DL3 in FIG. 11.

The red data line DL(R), which is the third data line DL3, can overlap the red pixel electrode PE(R).

The area 1200 where the green data line is omitted can be an area immediately adjacent to the red data line DL(R), which is the third data line DL3, and can overlap with the red pixel electrode PE(R).

In the upper area NA1 of the second area NA which is the general area NA, the red pixel electrode PE(R) can overlap with two data lines DL(R) and DL(G)_U. In addition, in the lower area NA2 of the second area NA which is the general area NA, the red pixel electrode PE(R) can overlap with two data lines DL(R) and DL(G)_D.

However, as described above, in the first area OA which is the optical area OA, the red pixel electrode PE(R) only overlaps with one data line DL(R). Accordingly, the light emission characteristics of the red subpixel in the first area OA can be different from the light emission characteristics of the red subpixel in the second area NA.

In order to reduce this deviation in light emission characteristics, as shown in FIGS. 12 and 13, the red data line DL(R), which is the third data line DL3, can include a protrusion 1210. The protrusion 1210 can overlap the red pixel electrode PE(R) in the first area OA.

For example, referring to FIGS. 12 and 13, the red data line DL(R), which is the third data line DL3, can overlap with the red subpixel PE(R) which is the eleventh subpixel PE11 of FIG. 11. The red data line DL(R) as the third data line DL3 can include a protrusion 1210 that protrudes into the area 1200 where the green data line is omitted.

The protrusion 1210 can overlap with the red subpixel PE(R) which is the eleventh subpixel PE11 of FIG. 11 in the data line longitudinal direction (e.g., column direction, data line extension direction).

Referring to FIGS. 12 and 13, the third pixel electrode PE3, the connection line CW and the fourth pixel electrode PE4 can be integrally formed. For example, the connection line CW can be composed of a pixel electrode material.

Referring to FIG. 12, in the first area OA, the first data line DL1 and the second data line DL2 can be disposed in the same metal layer (e.g., second metal layer) and spaced apart from each other on the same plane. Similarly, in the second area NA, the first data line DL1 and the second data line DL2 can be disposed in the same metal layer (e.g., second metal layer) and spaced apart from each other on the same plane.

Referring to FIG. 13, in at least a portion of the first area OA, the first data line DL1 and the second data line DL2 can be disposed in the different metal layers (e.g., a first metal layer and a second metal layer). Alternatively, in the second area NA, the first data line DL1 and the second data line DL2 can be disposed in the same metal layer (e.g., second metal layer).

For example, in the second area NA, the first data line DL1 and the second data line DL2 can be disposed in the same metal layer and spaced apart from each other on the same plane. In the transmission area TA among the transmission area TA and the non-transmission area NTA included in the first area OA, the first data line DL1 and the second data line DL2 can be disposed in different metal layers (e.g., first metal layer, second metal layer), and can overlap in the vertical direction. In the non-transmission area NTA among the transmission area TA and the non-transmission area NTA included in the first area OA, the first data line DL1 and the second data line DL2 can be disposed within the same metal layer (e.g., second metal layer) and spaced apart from each other on the same plane.

Referring to FIG. 13, for example, the first metal layer can be a metal layer between the second interlayer insulating layer 823 and the first planarization layer 831, and can be a first source-drain metal layer. The second metal layer can be a metal layer between the first planarization layer 831 and the second planarization layer 832, and can be a second source-drain metal layer. For example, the blue data line DL(B), which is the second data line DL2, can be disposed in the first metal layer, and the green data line DL(G), which is the first data line DL1, can be disposed in the second metal layer.

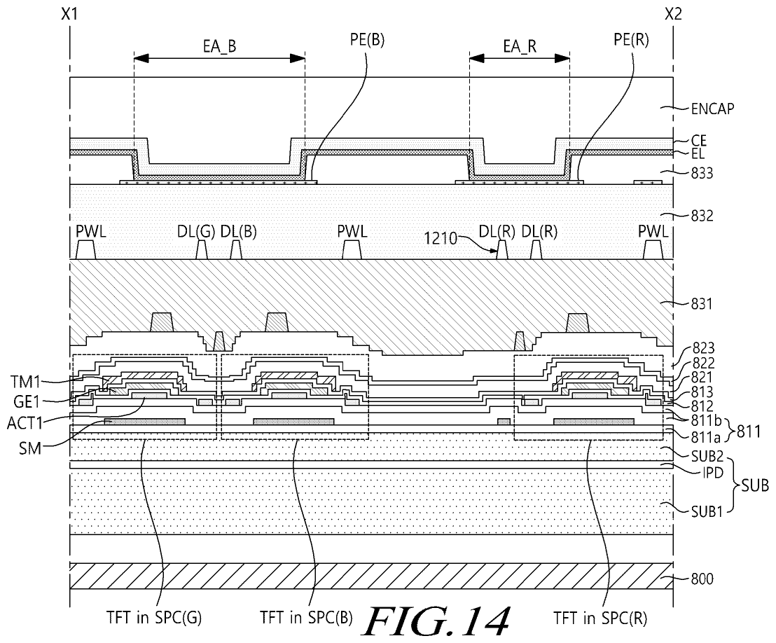

FIGS. 14 to 18 are cross-sectional views of the display panel 110 having a transmittance improvement structure according to embodiments of the present disclosure. However, in the cross-sectional views of FIGS. 14 to 18, the stacked structure is the same as that in FIGS. 8 and 9. Therefore, the description of the stacked structure will be omitted or may be briefly provided. Additionally, in the following description, FIGS. 11 to 13 are also referred to.

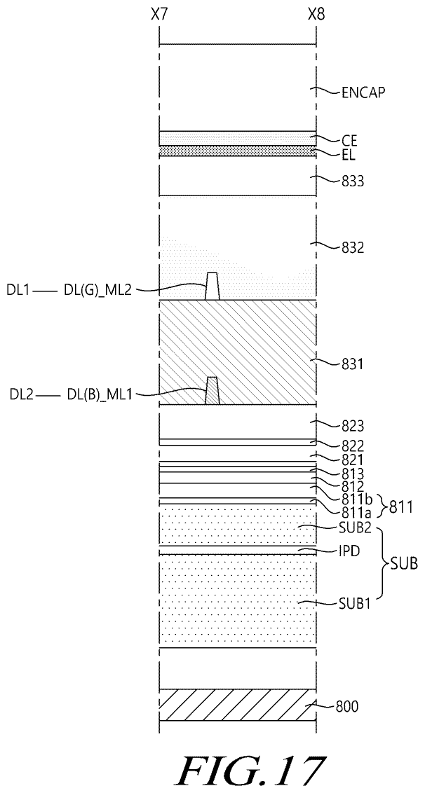

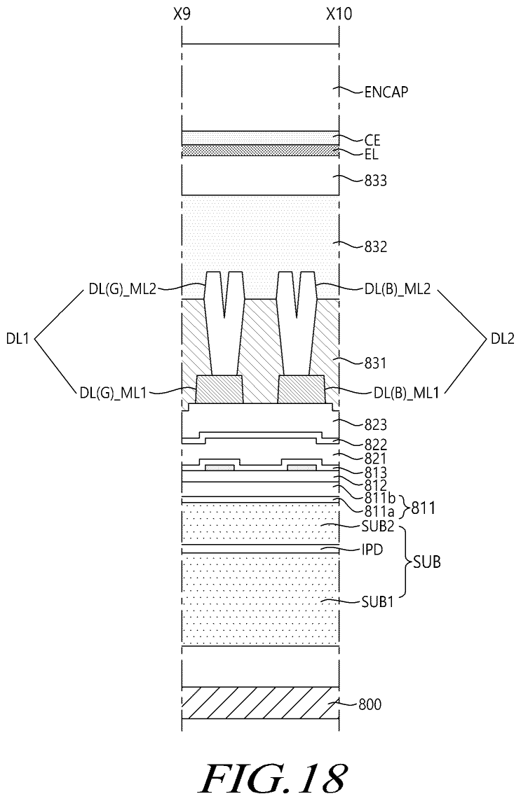

FIG. 14 is a cross-sectional view taken along line X1-X2 of FIGS. 12 and 13, FIG. 15 is a cross-sectional view taken along line X3-X4 of FIGS. 12 and 13, FIG. 16 is a cross-sectional view taken along line X5-X6 of FIG. 13, FIG. 17 is a cross-sectional view taken along line X7-X8 of FIG. 13, and FIG. 18 is a cross-sectional view taken along line X9-X10 of FIG. 13.

Referring to FIG. 14, in the area indicated by line X1-X2 of FIGS. 12 and 13, there can be a blue emission area EA_B of the blue subpixel and a red emission area EA_R of the red subpixel. For example, the blue pixel electrode PE(B) and the red pixel electrode PE(R) can be disposed in the area indicated by line X1-X2 in FIGS. 12 and 13.

In the area indicated by line X1-X2 of FIGS. 12 and 13, there can be disposed a transistor TFT included in the green subpixel circuit SPC(G), a transistor TFT included in the blue subpixel circuit SPC(B), and a transistor TFT included in the red subpixel circuit SPC(R).

These transistors TFT can include a first active layer ACT1 and a first gate electrode GE1 on the first active layer ACT1. The first active layer ACT1 is an active layer of the lower transistor, and can include a silicon-based semiconductor material. For example, the silicon-based semiconductor material can include low-temperature polycrystalline silicon (LTPS).

A shield metal SM which overlaps the first active layer ACT1 can be disposed under the transistors TFT. The shield metal SM can be disposed between the multi-buffer layer 811a and the active buffer layer 811b.

A first upper metal TM1 overlapping with the first gate electrode GE1 can be disposed on the transistors TFT. The first upper metal TM1 can be disposed between the first interlayer insulating layer 813 and the second buffer layer 821.

A metal layer between the second interlayer insulating layer 823 and the first planarization layer 831 can be referred to as the first metal layer, and a metal layer between the first planarization layer 831 and the second planarization layer 832 can be referred to as a second metal layer. The second metal layer is upper than (e.g., located above) the first metal layer.

A plurality of horizontal lines extending in the horizontal direction can be placed in the first metal layer, and a plurality of vertical lines extending in the vertical direction can be placed in the second metal layer.

Further, data lines DL(R), DL(G) and DL(B), which are a type of vertical line, can be disposed in the second metal layer. Additionally, a power line PWL, which is another type of vertical line, can also be disposed in the second metal layer.

Unlike the data lines DL(R), DL(G), and DL(B), the power line PWL can be a line to which a power supply voltage whose voltage level does not change according to frame changes is applied. For example, the power line PWL can include at least one of a driving voltage line VDDL and a base voltage line VSSL.

As described above, the power line PWL can be disposed in the same metal layer (e.g., second metal layer) as the vertical bypass line V_BW.

One of the two red data lines DL(R) overlapping the red pixel electrode PE(R) can correspond to the protrusion 1210 protruding from the red data line DL(R), which is the third data line DL3 in FIGS. 12 and 13.

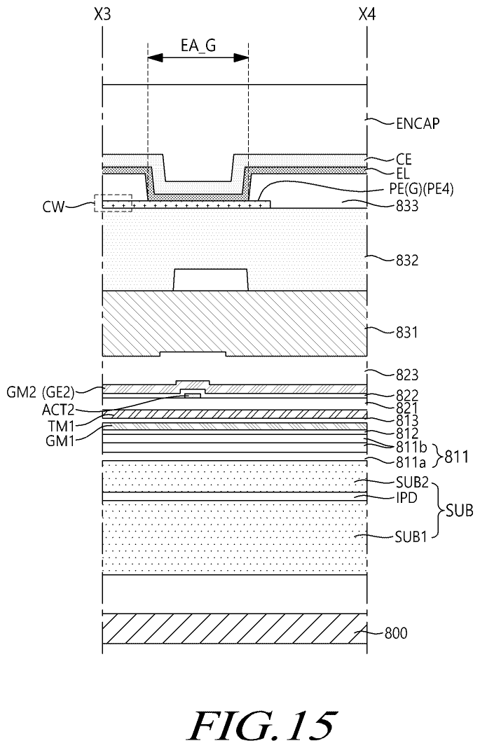

Referring to FIG. 15, the third pixel electrode PE3 and the fourth pixel electrode PE4, which are two green pixel electrodes PE(G), can be connected to each other through a connection line CW.

The third pixel electrode PE3 and the fourth pixel electrode PE4 can be formed integrally with the connection line CW.

Below the fourth pixel electrode PE4, there can be disposed a second gate metal GM2, which corresponds to a second active layer ACT2 on the second buffer layer 821 and a second gate electrode GE2 on the second active layer ACT2.

A first upper metal TM1 can be disposed between the first interlayer insulating layer 813 and the second buffer layer 821, and a first gate metal GM1 can be disposed between the first gate insulating layer 812 and the first interlayer insulating layer 813.

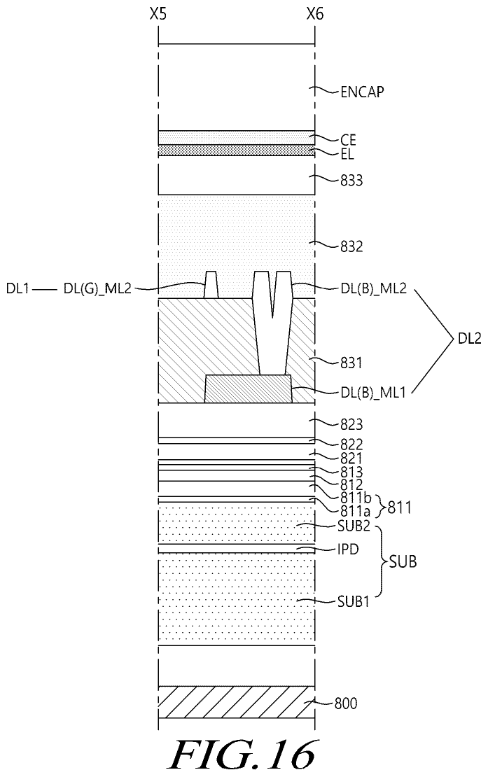

Referring to FIG. 16, the area marked with lines X5-X6 can be a boundary area between the transmission area TA and the non-transmission area NTA.

In an area indicated by line X5-X6, the second data line DL2 can include an upper layer portion disposed on the same second metal layer as the first data line DL1, a lower layer portion disposed on a first metal layer lower than the second metal layer, a connection portion connecting the upper layer and the lower layer, and an extension portion extending below the first data line DL1.

In the area indicated by line X5-X6, the second data line DL2 can go down in the vertical direction and shift in the horizontal direction to overlap the first data line DL1. Here, the first data line DL1 can be a green data line DL(G), and the second data line DL2 can be a blue data line DL(B).

In the area indicated by lines X5-X6, the first data line DL1 can be a first upper data line DL(G)_ML2 disposed on the second metal layer. The second data line DL2 can include a second lower data line DL(B)_ML1 disposed on the first metal layer and a second upper data line DL(B)_ML2 disposed on the second metal layer.

An upper blue data line DL(B)_ML2 as the second upper data line can be connected to a lower blue data line DL(B)_ML1 through a hole in the first planarization layer 831. A lower blue data line DL(B)_ML1 as the second lower data line can extend slightly in the horizontal direction and overlap the upper green data line DL(G)_ML2.

Referring to FIG. 17, the area indicated by lines X7-X8 is an area included in the transmission area TA. In the area indicated by lines X7-X8, the first data line DL1 and the second data line DL2 can overlap in the vertical direction.

In the area indicated by lines X7-X8, the first data line DL1 can be a first upper data line DL(G)_ML2 disposed on the second metal layer, and the second data line DL2 can be a second lower data line DL(B)_ML1 disposed on the first metal layer.

The area indicated by lines X7-X8 is an area included in the transmission area TA. In the area indicated by lines X7-X8, the first data line DL1 and the second data line DL2 can overlap in the vertical direction, thereby greatly improving the transmittance of the transmission area TA.

Referring to FIG. 18, the area indicated by line X9-X10 is included in the non-transmission area NTA, and can be a subpixel circuit area.

In the non-transmission area NTA, the first data line DL1 can include a first lower data line DL(G)_ML1 disposed within a first metal layer and a first upper data line DL(G)_ML2 disposed within a second metal layer different from the first metal layer.

The first lower data line DL(G)_ML1 and the first upper data line DL(G)_ML2 can be electrically connected to each other through holes in the first planarization layer 831, which is an insulating layer between the first metal layer and the second metal layer.

In the non-transmission area NTA, the second data line DL2 can include a second lower data line DL(B)_ML1 disposed in the first metal layer and a second upper data line DL(B)_ML2 disposed in the second metal layer.

The second lower data line DL(B)_ML1 and the second upper data line DL(B)_ML2 can be electrically connected to each other through different holes in the first planarization layer 831 which is an insulating layer.

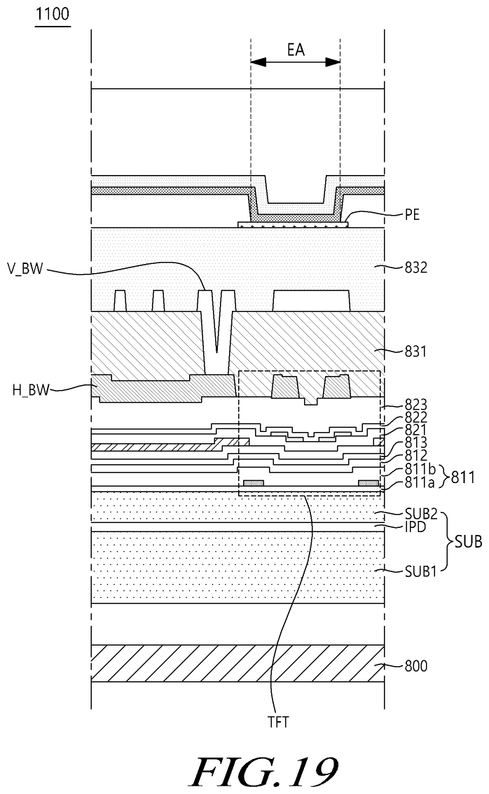

FIG. 19 is a cross-sectional view of a connection area between the vertical bypass line V_BW and the horizontal bypass line H_BW in the display panel 110 according to embodiments of the present disclosure. However, in the cross-sectional view of FIG. 19, the stacked structure is the same as that in FIGS. 8 and 9. Therefore, the description of the stacked structure will be omitted or may be briefly provided. Additionally, in the following description, FIGS. 11 to 13 are also referred to.

Referring to FIG. 19, the horizontal bypass line H_BW can be disposed on the first metal layer, and the vertical bypass line V_BW can be disposed on a second metal layer different from the first metal layer.

The vertical bypass line V_BW can be connected to the horizontal bypass line H_BW through a hole in the first planarization layer 831, which is an insulating layer disposed between the first metal layer and the second metal layer.

The area where the horizontal bypass line H_BW and the vertical bypass line V_BW are arranged can be the second area NA, which is the general area NA.

An emission area EA of a subpixel can exist in the second area NA, and there can be disposed a pixel electrode therefor. Additionally, there can be disposed a transistor TFT included in a subpixel circuit of a subpixel in the second area NA.

For example, each of the first subpixel SP1, the second subpixel SP2, the third subpixel SP3, the fifth subpixel SP5 and the sixth subpixel SP6 shown in FIG. 11 can include a light emitting device ED and a subpixel circuit SPC(G), and the subpixel circuit SPC(G) can include two or more transistors DT and ST.

The fourth subpixel SP4 can include the light emitting device ED, but may not include the subpixel circuit SPC(G). The source electrode and drain electrode of each of the two or more transistors can be disposed in the same first metal layer as the horizontal bypass line H_BW.

The first data line DL1, the upper data line DL(G)_U, and the lower data line DL(G)_D can be disposed in the same second metal layer as the vertical bypass line V_BW.

Referring to FIGS. 14 to 19, the display device 100 according to embodiments of the present disclosure can further include an electronic device 800 which is located below the substrate SUB, overlaps the first area OA, and performs a specified operation using light passing through the first area OA.

Embodiments of the present disclosure described above are briefly described as follows.

A display device according to embodiments of the present disclosure can include a substrate including a display area capable of displaying an image and a non-display area outside the display area, a plurality of subpixels included in the display area, each including a plurality of light emitting devices, and a plurality of data lines for supplying data signals for image display to the plurality of subpixels.

The display area can include a first area capable of transmitting light and a second area located outside the first area. The second area can include an upper area above the first area and a lower area under the first area.

The plurality of data lines can include a first data line extending from the upper area to the lower area passing through the first area, an upper data line disposed in the upper area, a lower data line disposed in the lower area, and a bypass line which electrically connects the upper data line and the lower data line and bypasses the first area.

The bypass line can include a first bypass line connected to the upper data line, a second bypass line connected to the lower data line, and a third bypass line for connecting the first bypass line and the second bypass line.

The bypass line can include a horizontal bypass line extending horizontally, and a vertical bypass line extending vertically, wherein the first bypass line and the second bypass line are horizontal bypass lines, and the third bypass line is a vertical bypass line.

The horizontal bypass line can be disposed in a first metal layer, and the vertical bypass line can be disposed in a second metal layer different from the first metal layer.

A display device according to embodiments of the present disclosure can further include a power line for applying a power voltage whose voltage level does not change depending on a frame change, wherein the power line is disposed in the second metal layer.

The power line can be disposed within the same metal layer as the vertical bypass line.

Each of the plurality of light emitting devices can include a plurality of pixel electrodes.

The plurality of pixel electrodes can include a first pixel electrode disposed in the upper area and included in a first subpixel, a second pixel electrode disposed in the upper area and included in a second subpixel, a third pixel electrode disposed in the first area and included in a third subpixel, a fourth pixel electrode disposed in the first area and included in a fourth subpixel, a fifth pixel electrode disposed in the lower area and included in a fifth subpixel, and a sixth pixel electrode disposed in the lower area and included in the sixth subpixel.

The first data line can be connected to the first subpixel, the third subpixel, and the fifth subpixel.

The upper data line can be connected to the second subpixel. The lower data line can be connected to the sixth subpixel.

In the display device according to embodiments of the present disclosure, the third pixel electrode and the fourth pixel electrode can be electrically connected to each other.

The emission color of each of the first subpixel, the second subpixel, the third subpixel, the fourth subpixel, the fifth subpixel, and the sixth subpixel can be the same.

Each of the first subpixel, the second subpixel, the third subpixel, the fifth subpixel, and the sixth subpixel can include a light emitting device and a subpixel circuit for driving the light emitting device. The subpixel circuit can include two or more transistors,

The fourth subpixel can include a light emitting device, but may not include a subpixel circuit. In this case, the light emitting device of the fourth subpixel can be driven by a subpixel circuit of the third subpixel.

A driving current output from the subpixel circuit of the third subpixel can be supplied to the third pixel electrode and the fourth pixel electrode.

The display device according to embodiments of the present disclosure can further include a connection line which is disposed in the first area and electrically connects the third pixel electrode and the fourth pixel electrode.

The third pixel electrode, the connection line and the fourth pixel electrode can be integrally formed.

The plurality of pixel electrodes can further include a seventh pixel electrode disposed in the upper area and included in a seventh subpixel, an eighth pixel electrode disposed in the second area and included in an eighth subpixel, and a ninth pixel electrode disposed in the lower area and included in the ninth subpixel.

The plurality of data lines can include a second data line connected to the seventh subpixel, the eighth subpixel and the ninth subpixel.

The emission color of each of the seventh subpixel, the eighth subpixel and the ninth subpixel can be different from an emission color of each of the first subpixel, the second subpixel, the third subpixel, the fourth subpixel, the fifth subpixel and the sixth subpixel.

The second data line can intersect and overlap a portion (e.g., the connection line) in which the third pixel electrode and the fourth pixel electrode are connected.

For example, in the first area and the second area, the first data line and the second data line can be disposed in the same metal layer and spaced apart from each other on the same plane.

As another example, the first data line and the second data line can be disposed in the same metal layer in the second area. The first data line and the second data line can be disposed on different metal layers in at least a partial area of the first area.

For example, in the second area, the first data line and the second data line can be disposed in the same metal layer and spaced apart from each other on the same plane. The first area can include a transmission area and a non-transmission area. The first data line and the second data line can be disposed in different metal layers and overlap in a vertical direction in the transmission area. The first data line and the second data line can be disposed in the same metal layer and spaced apart from each other on the same plane in the non-transmission area.

The plurality of pixel electrodes can further include a tenth pixel electrode disposed in the upper area and included in a tenth subpixel, an eleventh pixel electrode disposed in the first area and included in an eleventh subpixel, and a twelfth pixel electrode disposed in the lower area and included in the twelfth subpixel.

The plurality of data lines can further include a third data line connected to the tenth subpixel, the eleventh subpixel, and the twelfth subpixel,

The third data line can overlap with the tenth pixel electrode.

The third data line can include a protrusion, and the protrusion can overlap with the eleventh pixel electrode in a longitudinal direction of the data lines, wherein an emission color of each of the tenth subpixel, the eleventh subpixel and the twelfth subpixel is different from an emission color of each of the first subpixel, the second subpixel, the third subpixel, the fourth subpixel, the fifth subpixel and the sixth subpixel.

The display device according to embodiments of the present disclosure can further include a common electrode disposed on a plurality of pixel electrodes.

The common electrode can include a plurality of common electrode holes in the first area.

The display device according to embodiments of the present disclosure can further include an electronic device which is located below the substrate, overlaps with the first area, and perform a predetermined operation using light passing through the first area.

The display device according to embodiments of the present disclosure can further includea second interlayer insulating layer on the substrate; a first planarization layer on the second interlayer insulating layer; and a second planarization layer on the first planarization layer, wherein the first metal layer is between the second interlayer insulating layer and the first planarization layer, and the second metal layer is between the first planarization layer and the second planarization layer.

A display device according to embodiments of the present disclosure can include a substrate including a display area capable of displaying an image and a non-display area outside the display area, a plurality of subpixels included in the display area, each of the plurality of subpixels including a plurality of pixel electrodes, and a plurality of data lines for supplying data signals for image display to the plurality of subpixels.

The display area can include a first area capable of transmitting light and a second area located outside the first area.

The second area can include an upper area above the first area and a lower area under the first area.

The plurality of pixel electrodes can include a first pixel electrode disposed in the upper area and included in a first subpixel, a second pixel electrode disposed in the upper area and included in a second subpixel, a third pixel electrode disposed in the first area and included in a third subpixel, a fourth pixel electrode disposed in the first area and included in a fourth subpixel, a fifth pixel electrode disposed in the lower area and included in a fifth subpixel, and a sixth pixel electrode disposed in the lower area and included in the sixth subpixel,

The plurality of data lines can include a first data line extending from the upper area to the lower area passing through the first area, and connected to the first subpixel, the third subpixel, and the fifth subpixel, an upper data line disposed in the upper area and connected to the second subpixel, and a lower data line disposed in the lower area and connected to the sixth subpixel.

The third pixel electrode and the fourth pixel electrode can be electrically connected to each other.

The display device according to embodiments of the present disclosure can further include a connection line which is disposed in the first area and electrically connects the third pixel electrode and the fourth pixel electrode.

A display device according to embodiments of the present disclosure can include a substrate including a display area capable of displaying an image and a non-display area outside the display area; a plurality of subpixels included in the display area; and a plurality of data lines for supplying data signals for image display to the plurality of subpixels, wherein the display area comprises a first area capable of transmitting light and a second area located outside the first area, wherein a part of the plurality of data lines passes through the first area, and other of plurality of data lines bypass the first area.

According to embodiments of the present disclosure as described above, it is possible to provide a display device having a light-transmitting structure which allows an electronic device to normally receive light (e.g., visible light, infrared light, or ultraviolet light) without exposing the electronic device receiving light to the front.

According to embodiments of the present disclosure, it is possible to provide a display device capable of improving the transmittance of an optical area (e.g., a first area) through which light can pass through.

According to embodiments of the present disclosure, it is possible to provide a display device having a structure to reduce the metal ratio in an optical area (e.g., a first area) through which light can be transmitted.

According to embodiments of the present disclosure, it is possible to provide a display device having a panel structure capable of improving a detection performance of a detection sensor using light passing through an optical area (e.g., a first area).

According to embodiments of the present disclosure, it is possible to provide a display device having a panel structure capable of improving a performance of a camera using light passing through an optical area (e.g., a first area).

The above description and the accompanying drawings provide an example of the technical idea of the present disclosure for illustrative purposes only. Various modifications, additions and substitutions to the described embodiments will be readily apparent to those skilled in the art without departing from the spirit and scope of the present disclosure. In addition, the disclosed embodiments are intended to illustrate the scope of the technical idea of the present disclosure. Thus, the scope of the present disclosure is not limited to the embodiments shown.

What is claimed is:

1. A display device comprising:
a substrate including a display area configured to display an image and a non-display area located outside the display area;
a plurality of subpixels disposed in the display area, each of the plurality of subpixels including a plurality of light emitting devices; and
a plurality of data lines configured to supply data signals to the plurality of subpixels,
wherein the display area comprises a first area for transmitting light and a second area located outside the first area,
wherein the second area comprises an upper area above the first area and a lower area under the first area, and
wherein the plurality of data lines comprise:
an upper data line disposed in the upper area,
a lower data line disposed in the lower area, and
at least one bypass line configured to electrically connect the upper data line and the lower data line and bypass the first area.

2. The display device of claim 1, wherein the plurality of data lines further comprise:
a first data line extending from the upper area to the lower area.

3. The display device of claim 1, wherein the at least one bypass line comprises:
a first bypass line connected to the upper data line;
a second bypass line connected to the lower data line; and
a third bypass line for connecting the first bypass line and the second bypass line.

4. The display device of claim 1, wherein crossings between the at least one bypass line and the upper data line along with the lower data line have connecting points.

5. The display device of claim 3, wherein a first connecting point is formed at a crossing between the upper data line and the first bypass line, a second connecting point is formed at a crossing between the lower data line and the second bypass line, a third connecting point is formed at a crossing between the first bypass line and the third bypass line, and a fourth connecting point is formed at a crossing between the second bypass line and the third bypass line.

6. The display device of claim 1, wherein the at least one bypass line comprises a horizontal bypass line extending horizontally, and a vertical bypass line extending vertically.

7. The display device of claim 6, wherein a first connecting point is formed at a crossing between the upper data line and the horizontal bypass line, a second connecting point is formed at a crossing between the lower data line and the horizontal bypass line, a third connecting point and a fourth connecting point are formed at crossings between the horizontal bypass line and the vertical bypass line respectively.

8. The display device of claim 6, wherein the horizontal bypass line is disposed in a first metal layer, and the vertical bypass line is disposed in a second metal layer different from the first metal layer.

9. The display device of claim 8, wherein the second metal layer is located higher than the first metal layer.

10. The display device of claim 6, wherein the horizontal bypass line and the upper data line along with the lower data line form a mesh type.

11. The display device of claim 8, further comprising a power line configured to apply a power voltage having a voltage level that does not change depending on a frame change, and
wherein the power line is disposed in the second metal layer.

12. The display device of claim 1, wherein each of the plurality of light emitting devices includes a plurality of pixel electrodes,
wherein the plurality of subpixels comprise a first subpixel, a second subpixel, a third subpixel, a fourth subpixel, a fifth subpixel and a sixth subpixel,
wherein the plurality of pixel electrodes comprise:
a first pixel electrode disposed in the upper area and included in the first subpixel;
a second pixel electrode disposed in the upper area and included in the second subpixel;
a third pixel electrode disposed in the first area and included in the third subpixel;
a fourth pixel electrode disposed in the first area and included in the fourth subpixel;
a fifth pixel electrode disposed in the lower area and included in the fifth subpixel; and
a sixth pixel electrode disposed in the lower area and included in the sixth subpixel,
wherein the upper data line is connected to the second subpixel,
wherein the lower data line is connected to the sixth subpixel, and
wherein the third pixel electrode and the fourth pixel electrode are electrically connected to each other.

13. The display device of claim 12, wherein the plurality of data lines further comprise:
a first data line extending from the upper area to the lower area,
wherein the first data line is connected to the first subpixel, the third subpixel, and the fifth subpixel.

14. The display device of claim 13, wherein an emission color of each of the first subpixel, the second subpixel, the third subpixel, the fourth subpixel, the fifth subpixel, and the sixth subpixel is the same.

15. The display device of claim 13, wherein each of the first subpixel, the second subpixel, the third subpixel, the fifth subpixel, and the sixth subpixel includes a light emitting device and a subpixel circuit for driving the light emitting device, and the subpixel circuit includes two or more transistors, and
wherein the fourth subpixel includes a light emitting device, but does not include a subpixel circuit, and the light emitting device of the fourth subpixel is driven by a subpixel circuit of the third subpixel.

16. The display device of claim 15, wherein a driving current output from the subpixel circuit of the third subpixel is supplied to the third pixel electrode and the fourth pixel electrode.

17. The display device of claim 12, further comprising a connection line disposed in the first area and electrically connecting the third pixel electrode and the fourth pixel electrode.

18. The display device of claim 12, wherein the plurality of subpixels further comprise a seventh subpixel, an eighth subpixel and a ninth subpixel,
wherein the plurality of pixel electrodes comprise:
a seventh pixel electrode disposed in the upper area and included in the seventh subpixel;
an eighth pixel electrode disposed in the second area and included in the eighth subpixel; and
a ninth pixel electrode disposed in the lower area and included in the ninth subpixel, and
wherein an emission color of each of the seventh subpixel, the eighth subpixel and the ninth subpixel is different from an emission color of each of the first subpixel, the second subpixel, the third subpixel, the fourth subpixel, the fifth subpixel and the sixth subpixel.

19. The display device of claim 18, wherein the plurality of data lines comprise a second data line connected to the seventh subpixel, the eighth subpixel and the ninth subpixel.

20. The display device of claim 19, wherein the second data line intersects and overlaps a portion in which the third pixel electrode and the fourth pixel electrode are connected.

21. The display device of claim 19, wherein the plurality of data lines further comprise:
a first data line extending from the upper area to the lower area,
wherein, in the first area and the second area, the first data line and the second data line are disposed in the same metal layer and spaced apart from each other on the same plane.

22. The display device of claim 19, wherein the plurality of data lines further comprise:
a first data line extending from the upper area to the lower area,
wherein the first data line and the second data line are disposed in a same metal layer in the second area, and
wherein the first data line and the second data line are disposed on different metal layers in at least a partial area of the first area.

23. The display device of claim 22, wherein, in the second area, the first data line and the second data line are disposed in the same metal layer and spaced apart from each other on a same plane,
wherein the first area includes a transmission area and a non-transmission area,
wherein the first data line and the second data line are disposed in different metal layers and overlap in a vertical direction in the transmission area, and
wherein the first data line and the second data line are disposed in the same metal layer and spaced apart from each other on the same plane in the non-transmission area.

24. The display device of claim 12, wherein the plurality of subpixels further comprise a tenth subpixel, an eleventh subpixel and a twelfth subpixel,
wherein the plurality of pixel electrodes comprise:
a tenth pixel electrode disposed in the upper area and included in the tenth subpixel;
an eleventh pixel electrode disposed in the first area and included in the eleventh subpixel; and
a twelfth pixel electrode disposed in the lower area and included in the twelfth subpixel, and
wherein an emission color of each of the tenth subpixel, the eleventh subpixel and the twelfth subpixel is different from an emission color of each of the first subpixel, the second subpixel, the third subpixel, the fourth subpixel, the fifth subpixel and the sixth subpixel.

25. The display device of claim 24, wherein the plurality of data lines further include a third data line connected to the tenth subpixel, the eleventh subpixel, and the twelfth subpixel,
wherein the third data line overlaps the tenth pixel electrode, and
wherein the third data line includes a protrusion, and the protrusion overlaps with the eleventh pixel electrode in a longitudinal direction of the data lines.

26. The display device of claim 1, further comprising a common electrode disposed on a plurality of pixel electrodes,
wherein the common electrode includes a plurality of common electrode holes in the first area.

27. The display device of claim 1, further comprising an electronic device which is located below the substrate, overlaps with the first area, and performs a predetermined operation using light passing through the first area.

28. The display device of claim 8, further comprising:
a second interlayer insulating layer on the substrate;
a first planarization layer on the second interlayer insulating layer, and
a second planarization layer on the first planarization layer,
wherein the first metal layer is disposed between the second interlayer insulating layer and the first planarization layer, and the second metal layer is disposed between the first planarization layer and the second planarization layer.

29. A display device comprising:
a substrate including a display area configured to display an image and a non-display area located outside the display area;
a plurality of subpixels included in the display area, each of the plurality of subpixels including a plurality of pixel electrodes; and
a plurality of data lines configured to supply data signals to the plurality of subpixels,
wherein the display area comprises a first area capable of transmitting light and a second area located outside the first area,
wherein the second area comprises an upper area above the first area and a lower area under the first area,
wherein the plurality of subpixels comprise a first subpixel, a second subpixel, a third subpixel, a fourth subpixel, a fifth subpixel and a sixth subpixel,
wherein the plurality of pixel electrodes comprise:
a first pixel electrode disposed in the upper area and included in the first subpixel,
a second pixel electrode disposed in the upper area and included in the second subpixel,
a third pixel electrode disposed in the first area and included in the third subpixel,
a fourth pixel electrode disposed in the first area and included in the fourth subpixel,
a fifth pixel electrode disposed in the lower area and included in the fifth subpixel, and
a sixth pixel electrode disposed in the lower area and included in the sixth subpixel,
wherein the plurality of data lines comprise:
an upper data line disposed in the upper area and connected to the second subpixel, and
a lower data line disposed in the lower area and connected to the sixth subpixel, and
wherein the third pixel electrode and the fourth pixel electrode are electrically connected to each other.

30. The display device of claim 29, wherein the plurality of data lines further comprise:
a first data line extending from the upper area to the lower area, and connected to the first subpixel, the third subpixel, and the fifth subpixel.

31. The display device of claim 29, further comprising a connection line disposed in the first area and electrically connecting the third pixel electrode and the fourth pixel electrode.

32. A display device comprising:
a substrate including a display area configured to display an image and a non-display area located outside the display area;
a plurality of subpixels included in the display area; and
a plurality of data lines configured to display data signals to the plurality of subpixels,
wherein the display area comprises a first area for transmitting light and a second area located outside the first area. and
wherein the plurality of data lines bypass the first area.
